(19) United States
(12) Patent Application Publication
(10) Pub. No.: US 2025/0308613 A1
(43) Pub. Date: Oct. 2, 2025

(54) SCAN REGISTER CIRCUIT GENERATING POSITION INDEX SIGNAL THROUGH FAIL-BIT SCAN OPERATION AND MEMORY DEVICE INCLUDING THE SAME

(71) Applicant: Samsung Electronics Co., Ltd., Suwon-si (KR)

(72) Inventors: Makoto HIRANO, Suwon-si (KR); Sang Soo PARK, Suwon-si (KR); Seoyeon CHOI, Suwon-si (KR); Jae-Duk YU, Suwon-si (KR)

(73) Assignee: Samsung Electronics Co., Ltd., Suwon-si (KR)

(21) Appl. No.: 18/967,166

(22) Filed: Dec. 3, 2024

(30) Foreign Application Priority Data
Apr. 1, 2024 (KR) 10-2024-0043928

(51) Int. Cl. G11C 29/32; G11C 29/42

(52) U.S. Cl. CPC G11C 29/32; G11C 29/42; G11C 2029/3202

(57) ABSTRACT

A memory device includes a memory cell array configured to store data; a page buffer circuit configured to store data in the memory cell array or read data stored in the memory cell array; and a scan register circuit configured to receive pass/fail results of data from the page buffer circuit and store the pass/fail result in a plurality of scan registers. The scan register circuit is configured to use information of scan registers in which fail results are stored through a fail bit scan operation and to generate position index signals indicating the positions of the fail bits.

### CROSS-REFERENCE TO RELATED APPLICATIONS

This application claims priority under 35 U.S.C. § 119 to Korean Patent Application No. 10-2024-0043928 filed on Apr. 1, 2024, in the Korean Intellectual Property Office, the disclosures of which are incorporated by reference herein in their entireties.

### BACKGROUND

Various example embodiments described herein relate to a semiconductor memory device, and more particularly, relate to a scan register circuit that generates a position index signal through a fail bit scan operation and/or a memory device including the same.

Semiconductor memories may be classified as a volatile memory or a non-volatile memory, for example. Typically, the volatile memories (e.g., a dynamic random access memory (DRAM) and/or a static random access memory (SRAM)) may exhibit faster read and/or write speeds when compared to the non-volatile memory. However, data stored in the volatile memory may disappear when a power applied to the volatile memory is turned off. In contrast, the non-volatile memory may retain the data even when the power is turned off.

A representative example of the non-volatile memory may be a flash memory. The flash memory may be used as a storage device for electronic devices such as, but not limited to, one or more of computers, smart phones, digital cameras and the like. The flash memory may store multi-bit data of two or more bits in one memory cell. The flash memory may have at least one erase state and a plurality of program (e.g., writing) states depending on threshold voltage distributions.

The flash memory may include a page buffer circuit for storing data in a memory cell array or reading data stored in the memory cell array. The flash memory may obtain pass/fail results of data from the page buffer circuit and correct errors caused by fail bits. The flash memory needs to or is expected to accurately calculate the number and position of fail bits to effectively correct errors caused by fail bits.

### SUMMARY

Various example embodiments provide a scan register circuit that generates a position index signal through a fail bit scan operation and/or a memory device including the same.

According to some example embodiments, a memory device comprises a memory cell array configured to store data; a page buffer circuit configured to at least one of store data in the memory cell array or read data stored in the memory cell array; and a scan register circuit configured to receive pass/fail results of data from the page buffer circuit and store the pass/fail result in a plurality of scan registers. The scan register circuit is configured to use information of scan registers in which fail results are stored through a fail bit scan operation and to generate position index signals indicating the positions of the fail bits.

Alternatively or additionally according to some example embodiments, a scan register circuit of the memory device comprises a scan register array comprising a plurality of frames, each frame having a plurality of scan chain units, each scan chain unit having a plurality of scan registers, each scan register configured to store a pass/fail result of data; and a fail bit position finder configured to use information of scan registers in which fail results are stored through a fail bit scan operation and to generate position index signals indicating the positions of the fail bits.

Alternatively or additionally according to various example embodiments, a scan register circuit of a memory device comprises a scan register array having a plurality of frames, each frame having a plurality of scan chain units, each scan chain unit having a plurality of scan registers, each scan register configured to store a pass/fail result of data; and a fail bit position finder configured to use information of scan registers in which fail results are stored through a scan operation of the plurality of scan registers and to generate position index signals indicating the positions of the fail bits. The fail bit position finder is configured to receive the information of the scan registers where the fail results are stored and the information of the scan register where the fail result are first stored from each scan chain unit through a fail bit scan operation, and to output the position index signals representing row addresses and column addresses of the fail bits.

### BRIEF DESCRIPTION OF THE DRAWINGS

The above and other objects and features of inventive concepts will become apparent by describing in detail various example embodiments thereof with reference to the accompanying drawings.

FIG. 1 is a block diagram illustrating an example embodiment of a storage device according to various example embodiments.

FIG. 2 is a block diagram illustrating as an example embodiment of the memory device illustrated in FIG. 1.

FIG. 3 is a circuit diagram illustrating an example embodiment of a memory block BLK1 of the memory cell array illustrated in FIG. 2.

FIG. 4 is a circuit diagram illustrating cell strings selected by the first string selection line SSL1 from among the cell strings of the memory block BLK1 illustrated in FIG. 3.

FIG. 5 is a diagram illustrating an example embodiment of threshold voltage distributions of memory cells illustrated in FIG. 4.

FIG. 6 is a block diagram illustrating an example embodiment of the scan register circuit shown in FIG. 2.

FIGS. 7 and 8 are circuit diagrams illustrating example embodiments of the first scan chain unit shown in FIG. 6.

FIG. 9 is a conceptual diagram illustrating an example embodiment of a position search operation of the scan register circuit shown in FIG. 6.

FIG. 10 is a block diagram for explaining the position search operation of the scan register circuit shown in FIG. 9.

FIGS. 11 and 12 are tables for explaining the operation of the 16×4 encoder and 8×3 encoder shown in FIG. 10.

FIG. 13 is a circuit diagram illustrating an example embodiment of the position search operation of the first scan chain unit shown in FIG. 10.

FIGS. 14 to 18 are diagrams illustrating example embodiments of the position search operation during the first to fifth cycles of the scan register circuit shown in FIG. 10.

FIG. 19 is a timing diagram illustrating the position search operation during the first to fifth cycles of the scan register circuit shown in FIG. 10.

FIGS. 20 to 22 are block diagrams for explaining an embodiment of the position search operation of the scan register circuit shown in FIG. 2.

FIG. 23 is a diagram illustrating the position index signal of the scan register circuit shown in FIG. 20.

FIGS. 24 to 29 are block diagrams for explaining an operation of calculating position index signals and RLE signals of first to fourth fail bits.

FIG. 30 is a flowchart for explaining the operation method of the scan register circuit shown in FIG. 20.

FIG. 31 is a diagram illustrating an example embodiment of a memory device having a multi-stack structure.

FIG. 32 is a block diagram illustrating an example in which a storage device according to various example embodiments is implemented with a solid state drive (SSD).

### DETAILED DESCRIPTION

Below, some example embodiments will be described in detail and clearly to such an extent that an ordinary one in the art easily implements inventive concepts.

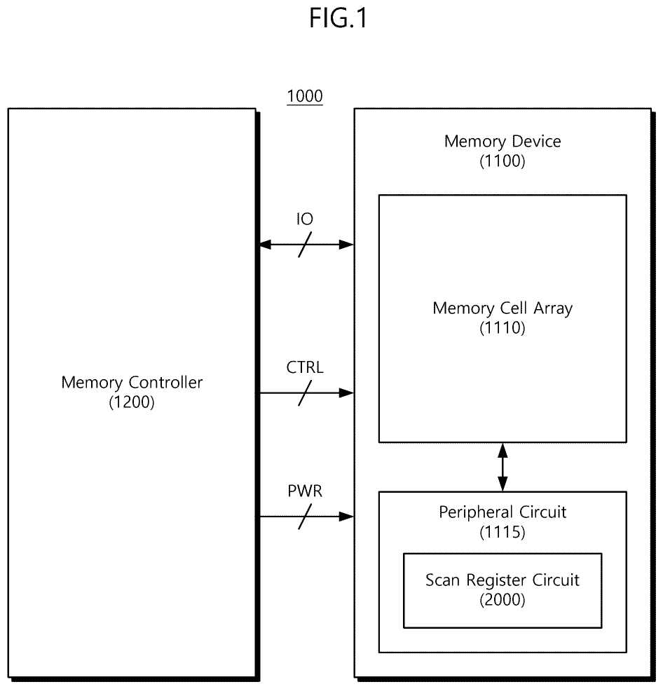

FIG. 1 is a block diagram illustrating an example embodiment of a storage device according to some example embodiments. The storage device 1000 may be a flash storage device based on a flash memory. For example, the storage device 1000 may be implemented as or may be included in a system included in one or more of a solid-state drive (SSD), a universal flash storage (UFS), a memory card, or the like.

Referring to FIG. 1, the storage device 1000 may include a memory device 1100 and a memory controller 1200. The memory device 1100 may receive input/output signals IO from the memory controller 1200 through input/output lines, may receive control signals CTRL through control lines, and may receive external power supply PWR through power lines. The storage device 1000 may store data in the memory device 1100 under the control of the memory controller 1200.

The memory device 1100 may include a memory cell array 1110 and a peripheral circuit 1115. The memory cell array 1110 may have a vertical 3D structure; however, example embodiments are not limited thereto. The memory cell array 1110 may include a plurality of memory cells. Single-bit data and/or multi-bit data may be stored in each memory cell.

The memory cell array 1110 may be located (e.g., disposed) next to or above the peripheral circuit 1115 in terms of the design layout structure; example embodiments are not limited thereto. A structure in which the memory cell array 1110 is positioned over the peripheral circuit 1115 may be referred to as a cell on peripheral (COP) structure.

The memory cell array 1110 may be manufactured as a chip separate from the peripheral circuit 1115; however, example embodiments are not limited thereto. An upper chip including the memory cell array 1110 and a lower chip including the peripheral circuit 1115 may be connected to each other by a bonding method. Such a structure may be referred to as a chip-to-chip (C2C) structure.

The peripheral circuit 1115 may include analog circuits and/or digital circuits to store data in the memory cell array 1110 and/or read data stored in the memory cell array 1110. The peripheral circuit 1115 may receive the external power PWR through power lines and generate internal powers of various levels.

The peripheral circuit 1115 may receive commands, addresses, and/or data from the memory controller 1200 through input/output lines. The peripheral circuit 1115 may store data in the memory cell array 1110 according to the control signals CTRL. Alternatively or additionally, the peripheral circuit 1115 may read data stored in the memory cell array 1110 and may provide the read data to the memory controller 1200.

The peripheral circuit 1115 may include a scan register circuit 2000. The scan register circuit 2000 may perform a position search operation. The scan register circuit 2000 may have a plurality of scan chain units, and each scan chain unit may have a plurality of scan registers. A pass/fail result of data stored in the memory cell array 1110 may be stored in each scan register. The scan register circuit 2000 may calculate the position of fail bits through the position search operation.

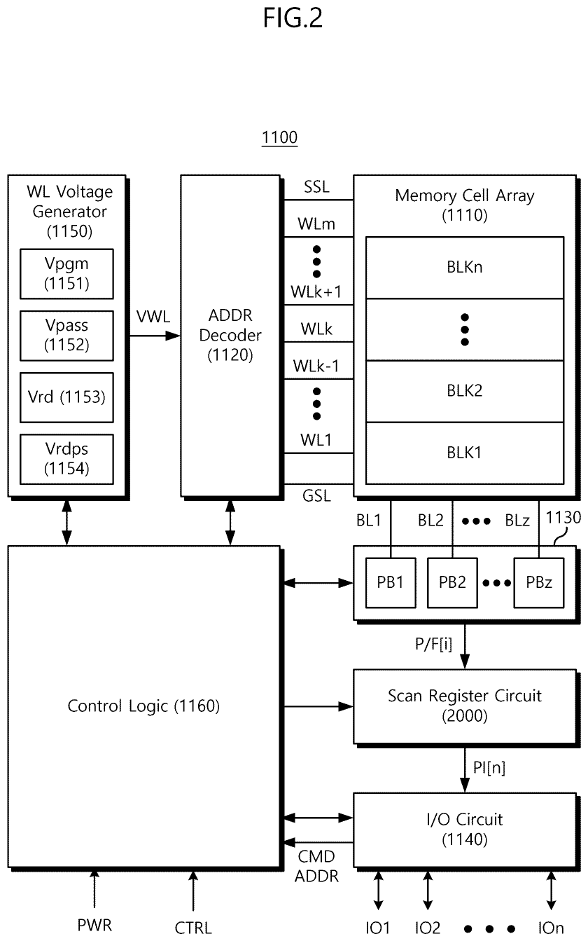

FIG. 2 is a block diagram illustrating as an example embodiment of the memory device illustrated in FIG. 1. Referring to FIG. 2, the memory device 1100 may include the memory cell array 1110 and the peripheral circuit 1115 (see FIG. 1). The peripheral circuit 1115 may include an address decoder 1120, a page buffer circuit 1130, a data input/output circuit 1140, a word line voltage generator 1150, and a control logic 1160.

The memory cell array 1110 may include a plurality of memory blocks BLK1 to BLKn. Each memory block may include a plurality of pages. Each page may include a plurality of memory cells. Each memory cell may store single-bit and/or multi-bit data (e.g., two or more bits); however, example embodiments are not limited thereto. Each memory block may correspond to an erase unit, and each page may correspond to a read and/or write unit.

The memory cell array 1110 may be formed in a direction perpendicular to a substrate. A gate electrode layer and an insulation layer may be alternately deposited on the substrate. Each memory block (e.g., BLK1) may be connected to one or more string selection lines SSL, a plurality of word lines WL1 to WLm, and one or more ground selection lines GSL. WLk is a selected word line sWL and the remaining word lines (WL1 to WLk−1, WLk+1 to WLm) are unselected word lines uWL. Example embodiments are not limited thereto. Here, m may be greater than, less than, or equal to n.

The address decoder 1120 may be connected to the memory cell array 1110 through selection lines SSL and GSL and word lines WL1 to WLm. The address decoder 1120 may select a word line during a program or read operation. The address decoder 1120 may receive the word line voltage VWL from the word line voltage generator 1150 and may provide a program voltage or read voltage to the selected word line.

The page buffer circuit 1130 may be connected to the memory cell array 1110 through bit lines BL1 to BLz. Here, z may be greater than, less than, or equal one or both of m and n. The page buffer circuit 1130 may temporarily store data to be stored in the memory cell array 1110 and/or data read from the memory cell array 1110. The page buffer circuit 1130 may include page buffers PB1 to PBz connected to respective bit lines. Each page buffer may include a plurality of latches to store or read multi-bit data.

The input/output circuit 1140 may be internally connected to the page buffer circuit 1130 through data lines and externally connected to the memory controller 1200 (refer to FIG. 1) through the input/output lines IO1 to Ion. The input/output circuit 1140 may receive program data from the memory controller 1200 during a program operation. Also, the input/output circuit 1140 may provide data read from the memory cell array 1110 to the memory controller 1200 during a read operation.

The word line voltage generator 1150 may receive internal power from the control logic 1160 and generate a word line voltage VWL required to read or write data. The word line voltage VWL may be provided to a selected word line sWL or unselected word lines uWL through the address decoder 1120.

The word line voltage generator 1150 may include a program voltage generator 1151 and a pass voltage generator 1152. The program voltage generator 1151 may generate a program voltage Vpgm provided to the selected word line sWL during a program operation. The pass voltage generator 1152 may generate a pass voltage Vpass provided to the selected word line sWL and the unselected word lines uWL.

The word line voltage generator 1150 may include a read voltage generator 1153 and a read pass voltage generator 1154. The read voltage generator 1153 may generate a select read voltage Vrd provided to the select word line sWL during a read operation. The read pass voltage generator 1154 may generate a read pass voltage Vrdps provided to unselected word lines uWL. The read pass voltage Vrdps may be a voltage sufficient to turn on memory cells connected to the unselected word lines uWL during a read operation.

The control logic 1160 may control operations such as read, write, and erase of the memory device 1100 using commands CMD, addresses ADDR, and control signals CTRL provided from the memory controller 1200. The addresses ADDR may include a block selection address for selecting one memory block, a row address for selecting one page, and a column address for selecting one memory cell.

The scan register circuit 2000 may receive a pass/fail result P/F[i] from the page buffer circuit 1130 and may output a position index signal PI. The memory device 1100 according to various example embodiments may calculate the position of fail bits using the scan register circuit 2000.

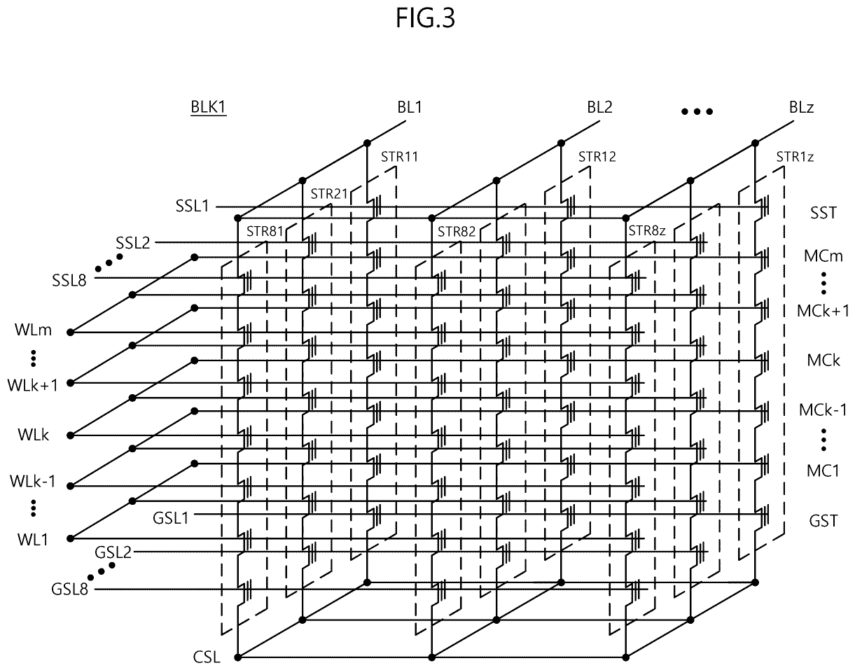

FIG. 3 is a circuit diagram illustrating example embodiments of a memory block BLK1 of the memory cell array illustrated in FIG. 2. Referring to FIG. 3, in the memory block BLK1, a plurality of cell strings STR11 to STR8z may be formed between the bit lines BL1 to BLZ and a common source line CSL. Each cell string includes a string selection transistor SST, a plurality of memory cells MC1 to MCm, and a ground selection transistor GST. There may or may not be dummy cells that are not activated during operation of the semiconductor device; example embodiments are not limited thereto.

The string selection transistors SST may be connected with string selection lines SSL1 to SSL8. The ground selection transistors GST may be connected with ground selection lines GSL1 to GSL8. The string selection transistors SST may be connected with the bit lines BL1 to BLz, and the ground selection transistors GST may be connected with the common source line CSL.

The first to m-th word lines WL1 to WLm may be connected with the plurality of memory cells MC1 to MCm in a row direction. The first to z-th bit lines BL1 to BLz may be connected with the plurality of memory cells MC1 to MCm in a column direction. First to z-th page buffers PB1 to PBz may be connected with the first to z-th bit lines BL1 to BLZ.

The first word line WL1 may be placed above the first to eighth ground selection lines GSL1 to GSL8. The first memory cells MC1 that are placed at the same height from the substrate may be connected with the first word line WL1. The m-th word line WLm may be located below the first to eighth string selection lines SSL1 to SSL8. The m-th memory cells MCm located at the same height from the substrate may be connected to the m-th word line WLm. In a similar manner, the second to (m−1)-th memory cells MC2 to MCm−1 that are placed at the same heights from the substrate may be respectively connected with the second to (m−1)-th word lines WL2 to WLm−1, respectively.

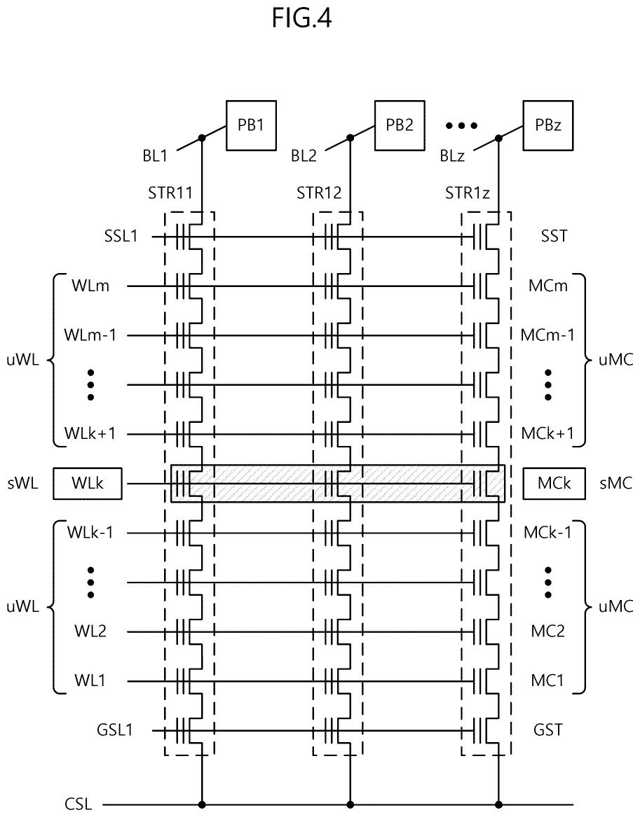

FIG. 4 is a circuit diagram illustrating cell strings selected by the first string selection line SSL1 from among the cell strings of the memory block BLK1 illustrated in FIG. 3.

The 11-th to 1z-th cell strings STR11 to STR1z may be selected by the first string selection line SSL1. The 11-th to 1z-th cell strings STR11 to STR1z may be connected to the first to z-th bit lines BL1 to BLz, respectively. The first to z-th page buffers PB1 to PBz may be connected to the first to z-th bit lines BL1 to BLz, respectively.

The 11-th cell string STR11 may be connected to the first bit line BL1 and the common source line CSL. The 11-th cell string STR11 may include string selection transistors SST selected by the first string selection line SSL1, first to m-th memory cells MC1 to MCm connected to the first to m-th word lines WL1 to WLm, and ground selection transistors GST selected by the first ground selection line GSL1. The 12-th cell string STR12 may be connected to the second bit line BL2 and the common source line CSL. The 1z cell string STR1z may be connected to the z-th bit line BLz and the common source line CSL.

The first word line WL1 and the m-th word line WLm may be edge word lines (edge WL). The second word line WL2 and the (m−1)-th word line WLm−1 may be edge adjacent word lines. The k-th word line WLk may be a selected word line sWL. The (k−1)-th word line WLk−1 and the (k+1)-th word line WLk+1 may be adjacent word lines adjacent to the selected word line. If the k-th word line WLk is the selected word line sWL, the remaining word lines WL1 to WLk−1 and WLk+1 to WLm may be unselected word lines uWL.

The first memory cells MC1 and the m-th memory cells MCm may be edge memory cells, e.g., memory cells on an edge of an array or subarray. The second memory cells MC2 and the (m−1)-th memory cells MCm−1 may be edge adjacent memory cells. The k-th memory cells MCk may be selected memory cells sMC. The (k−1)-th memory cells MCk−1 and the (k+1)-th memory cells MCk+1 may be memory cells adjacent to the selected memory cells (adjacent MC). If the k-th memory cells MCk are selected memory cells sMC, the remaining memory cells MC1 to MCk−1 and MCk+1 to MCm may be unselected memory cells uMC.

A set of memory cells selected by one string selection line and connected to one word line may be or may correspond to one page. For example, memory cells selected by the first string selection line SSL1 and connected to the k-th word line WLk may be one page. For example, eight pages may be configured on the k-th word line WLk. Among the eight pages, a page connected to the first string selection line SSL1 is a selected page, and pages connected to the second to eighth string selection lines SSL2 to SSL8 are unselected pages.

The first word line WL1 is a first edge word line (Edge1 WL), and the second word line WL2 is a first edge adjacent word line (Edge1 adjacent WL). The m-th word line WLm is the second edge word line (Edge2 WL), and the (m−1)-th word line WLm−1 is the second edge adjacent word line (Edge2 adjacent WL). And word lines between the first and second edge adjacent word lines are middle word lines. For example, the k-th word line WLk (k=3 to m−2) between the second word line WL2 and the (m−1)-th word line WLm−1 is a middle word line.

In a read operation, if the second word line WL2 is the selected word line sWL, the remaining word lines may be unselected word lines uWL. The second word line WL2 may be a first edge adjacent word line (Edge1 adjacent WL). The second memory cells MC2 may be selected memory cells sMC. The remaining memory cells may be unselected memory cells uMC.

If the (m−1)-th word line WLm−1 is the selected word line sWL, the remaining word lines may be unselected word lines uWL. The (m−1)-th word line WLm−1 may be a second edge adjacent word line. The (m−1)-th memory cells MCm−1 may be selected memory cells sMC. The remaining memory cells may be unselected memory cells uMC.

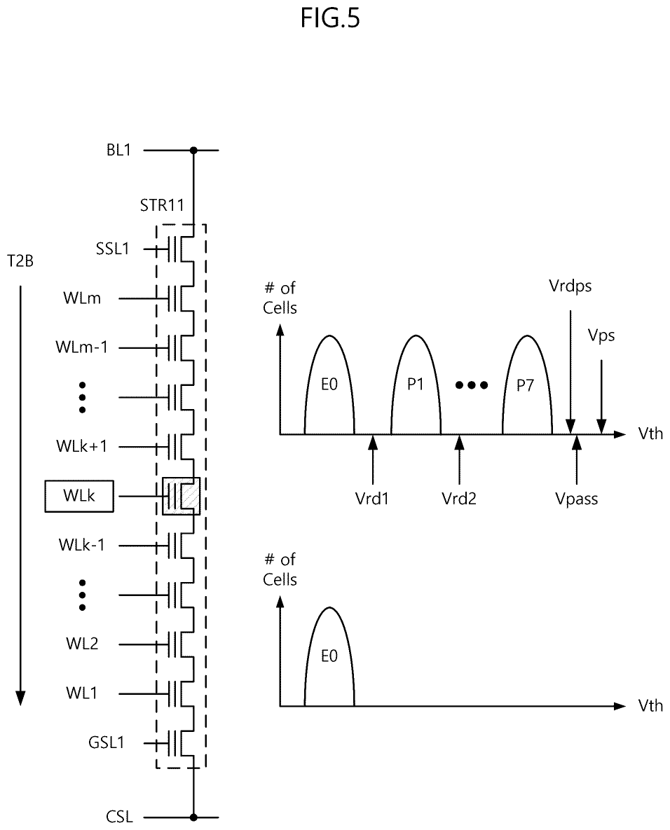

FIG. 5 is a diagram illustrating threshold voltage distributions of memory cells illustrated in example embodiments of FIG. 4. The horizontal axis represents the threshold voltage Vth, and the vertical axis represents the number of memory cells. FIG. 5 shows an example in which 3-bit data is stored in one memory cell. A 3-bit memory cell may have one of eight states (E0, P1 to P7) according to the threshold voltage distribution. E0 represents an erase state, and P1 to P7 represent program states.

During a read operation, the selection read voltages Vrd1 to Vrd7 may be provided to the selected word line sWL, and the pass voltage Vps and/or the read pass voltage Vrdps may be provided to the unselected word lines uWL. The pass voltage Vps and/or the read pass voltage Vrdps may be a voltage sufficient to turn on the memory cells. For example, the pass voltage Vps may be provided to the adjacent word lines WLk+1, and the read pass voltage Vrdps may be provided to the unselected word lines other than the adjacent word lines.

The first selection read voltage Vrd1 may be a voltage level between the erase state E0 and the first program state P1. The second selection read voltage Vrd2 may be a voltage level between the first and second program states P1 and P2. In this way, the seventh selection read voltage Vrd7 may be a voltage level between the sixth and seventh program states P6 and P7.

When the first selection read voltage Vrd1 is applied, the memory cell in the erase state E0 may be an on cell or may be turned on and the memory cell in the first to seventh program states P1 to P7 may be an off cell or may be turned off. When the second selection read voltage Vrd2 is applied, the memory cell in the erase state E0 and the first program state P1 may an on cell or turned on, and the memory cell in the second to seventh program states P2 to P7 may an off cell or may be turned off. In this way, when the seventh selection read voltage Vrd7 is applied, the memory cell in the erase state E0 and the first to sixth program states P1 to P6 may be an on cell and the memory cell in the seventh program state P7 may be an off cell.

During a read operation, the k-th word line WLk may be selected. A power supply voltage may be applied to the string selection line SSL1 and the ground selection line GSL1, and the string select transistor SST and the ground select transistor GST may be turned on. Also, the selection read voltage Vrd may be provided to the selected word line sWL, and the read pass voltage Vrdps and/or the pass voltage Vps may be provided to the unselected word lines uWL.

When the read operation of the k-th word line WLk is repeatedly performed, the high voltage read pass voltage Vrdps may be repeatedly provided to the remaining word lines. At this time, a read disturbance may occur in the remaining word lines, and thus the threshold voltage may be distorted, e.g., increased or decreased. Memory cells connected to the k-th word line WLk may be off cells when a selection read voltage is provided. For example, when the threshold voltage of the k-th memory cell is higher than the selection read voltage, the k-th memory cell may be an off cell. When the k-th memory cell is an off cell, a channel may be separated at the k-th memory cell. For example, a lower channel of the k-th memory cell may receive a ground voltage from the common source line CSL, and an upper channel of the k-th memory cell may have a negative channel voltage.

A channel voltage difference may occur between a lower channel and an upper channel with the k-th memory cell interposed therebetween. Due to the channel voltage difference, hot carrier injection (HCl) may occur in an adjacent memory cells MCk+1 and/or MCk−1. For this reason, threshold voltages of memory cells connected to adjacent word lines WLk+1 and/or WLk−1 may be distorted. For example, the threshold voltages of memory cells in the erased state E0 may rise to enter the programmed state.

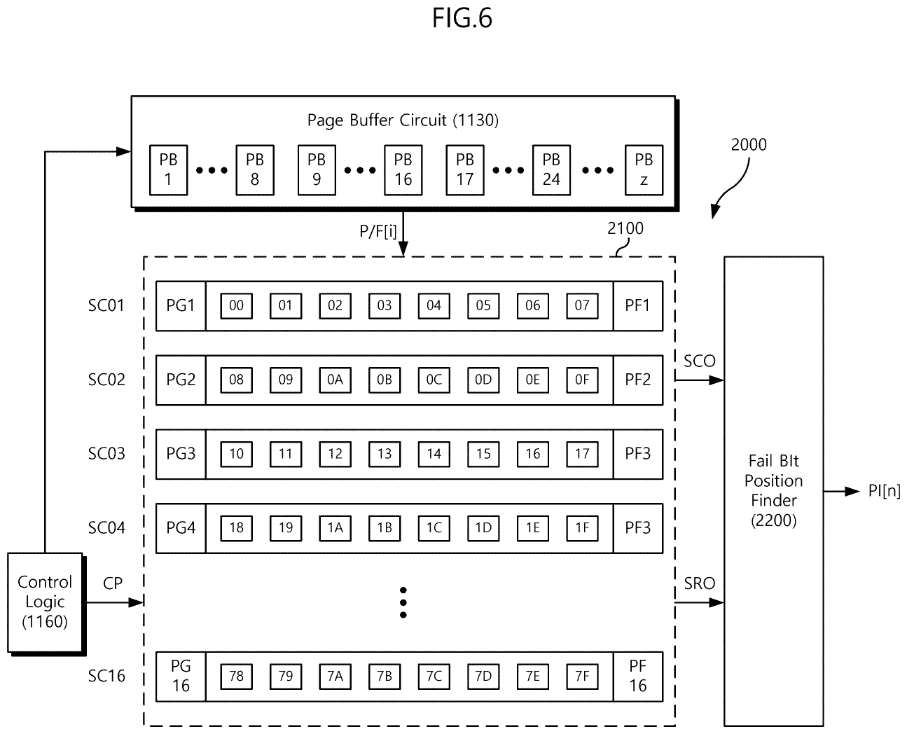

FIG. 6 is a block diagram illustrating various example embodiments of the scan register circuit shown in FIG. 2. Referring to FIG. 6, the scan register circuit 2000 may include a scan register array 2100 and a fail bit position finder 2200.

The scan register array 2100 may include a plurality of scan chain units. For example, the scan register array 2100 may include first to sixteenth scan chain units SC01 to SC16. Each scan chain unit may include a pulse gate PG, scan registers, and a priority filter PF.

For example, the first scan chain unit SC01 may include a first pulse gate PG1, first scan registers 00 to 07, and a first priority filter PF1. The second scan chain unit SC02 may include a second pulse gate PG2, second scan registers 08 to 0F, and a second priority filter PF2. As such, the 16-th scan chain unit SC16 may include a 16th pulse gate PG16, 16th scan registers 78 to 7F, and a 16th priority filter PF16.

Each scan chain unit may have the same or similar internal configuration and operating principle; however, example embodiments are not necessarily limited thereto. Hereinafter, the internal configuration and operating principle of the first scan chain unit SC01 will be described. The first pulse gate PG1 of the first scan chain unit SC01 may receive a clear pulse CP from the control logic 1160 and provide a clock signal to the first scan registers 00 to 07.

The pass/fail result P/F[i] for the data of the page buffers may be input to the first scan registers 00 to 07. For example, the pass/fail result for the data of the first to eighth page buffers PB1 to PB8 may be input to the first scan registers 00 to 07 of the first scan chain unit SC01. The pass/fail result [P/F[1] for the data of the first page buffer PB1 may be input to the 00 scan register.

The pass/fail result for the data of the 9th to 16th page buffers PB9 to PB16 may be input to the second scan registers 08 to 0F of the second scan chain unit SC02. The pass/fail result for the data of the 17th to 24th page buffers PB17 to PB24 may be input to the third scan registers 10 to 17 of the third scan chain unit SC03. In this way, the pass/fail result may also be input to the scan registers of the 16th scan chain unit SC16.

The fail bit position finder 2200 may receive a scan chain output signal SCO and a scan register output signal SRO from the first to sixteenth scan chain units SC01 to SC16. The fail bit position finder 2200 may detect the position of the fail bit and output a position index signal PI[n].

The scan register circuit of the memory device according to various example embodiments may include a scan register array 2100 and a fail bit position finder 2200. The scan register array 2100 may have a plurality of scan chain units, each scan chain unit may have a plurality of scan registers, and each scan register may store a pass/fail result of data. The fail bit position finder 2200 may obtain information on the scan register where the fail result is stored through a scan operation of a plurality of scan registers. Furthermore, the fail bit position finder 2200 may calculate the position of fail bits according to the operation mode using the information on the scan register where the fail result is stored. A position index indicating the position of the fail bit may be calculated.

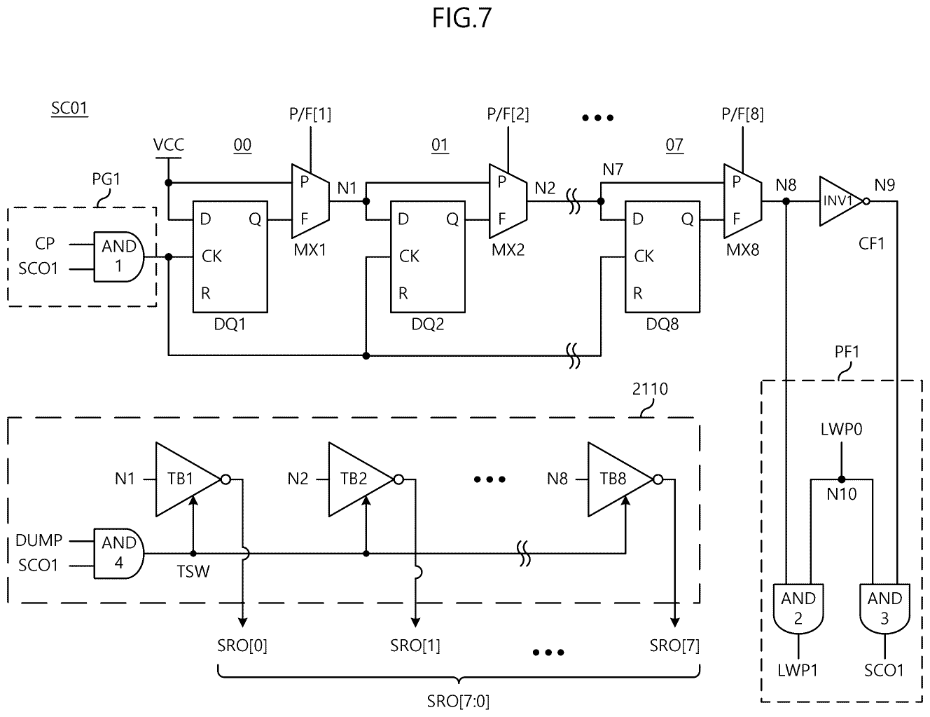

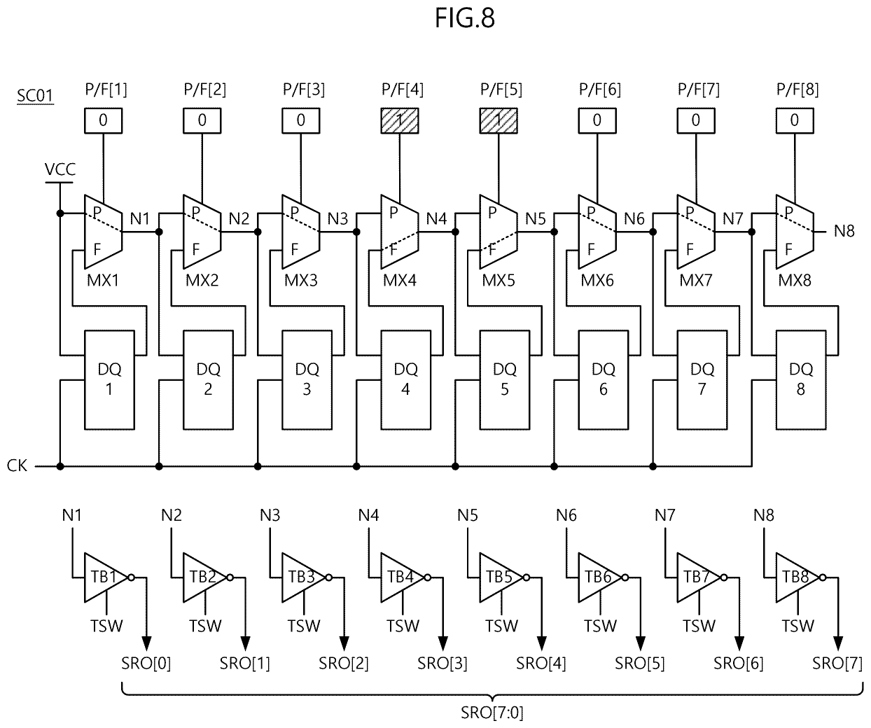

FIGS. 7 and 8 are circuit diagrams illustrating example embodiments of the first scan chain unit shown in FIG. 6. Referring to FIGS. 7 and 8, the first scan chain unit SC01 may include a first pulse gate PG1, first scan registers 00 to 07, a first priority filter PF1, and a scan register output circuit 2110.

The first pulse gate PG1 may receive the clear pulse CP and the first scan chain output signal SCO1 and perform AND logic operation. For example, the first pulse gate PG1 may include a first AND gate AND1. The first AND gate AND1 may receive a clear pulse CP and a first scan chain output signal SCO1 and generate a clock signal. The clock signal may be provided to first scan registers 00 to 07.

The 00-th scan register may include a first flip-flop DQ1 and a first multiplexer MX1. The first flip-flop DQ1 may include a D terminal, a CK terminal, an R terminal, and a Q terminal. The D terminal may be connected to the power terminal, and the CK terminal may be connected to the output terminal of the first pulse gate PG1. The first flip-flop DQ1 may receive a power supply voltage VCC through the D terminal, a clock signal through the CK terminal, and a reset signal through the R terminal. The first flip-flop DQ1 may output an output signal through the Q terminal.

The first multiplexer MX1 may include a P terminal and an F terminal. The P terminal may be connected to the power terminal, and the F terminal may be connected to the Q terminal of the first DQ flip-flop DQ1. The first multiplexer MX1 may receive the first pass/fail result P/F[1], select one of the P terminal and the F terminal, and connect it to the first node N1. For example, if the first pass/fail result P/F[1] is a pass, the P terminal may be connected to the first node N1. And if the first pass/fail result P/F[1] is a fail, the F terminal may be connected to the first node N1.

The 01 scan register may include a second flip-flop DQ2 and a second multiplexer MX2. The D terminal of the second flip-flop DQ2 may be connected to the first node N1. The second DQ flip-flop DQ2 may receive a clock signal through the CK terminal and a reset signal through the R terminal. The second flip-flop DQ2 may output an output signal through the Q terminal.

The P terminal of the second multiplexer MX2 may be connected to the first node N1, and the F terminal may be connected to the Q terminal of the second flip-flop DQ2. The second multiplexer MX2 may receive the second pass/fail result P/F[2], select one of the P terminal and the F terminal, and connect it to the second node N2. For example, if the second pass/fail result P/F[2] is a pass, the P terminal may be connected to the second node N2. Further, if the second pass/fail result P/F[2] is a fail, the F terminal may be connected to the second node N2.

The 07 scan register may include an eighth flip-flop DQ8 and an eighth multiplexer MX8. The D terminal of the eighth flip-flop DQ8 may be connected to the seventh node N7. The eighth flip-flop DQ8 may receive a clock signal through the CK terminal and a reset signal through the R terminal. The eighth flip-flop DQ8 may output an output signal through the Q terminal.

The P terminal of the eighth multiplexer MX8 may be connected to the seventh node N7, and the F terminal may be connected to the Q terminal of the eighth flip-flop DQ8. The eighth multiplexer MX8 may receive the eighth pass/fail result P/F[8], select one of the P terminal and the F terminal, and connect it to the eighth node N8. For example, if the eighth pass/fail result P/F[8] is a pass, the P terminal may be connected to the eighth node N8. Further, if the eighth pass/fail result P/F[8] is a fail, the F terminal may be connected to the eighth node N8.

Although the scan register is described as including a DQ flip-flop and a multiplexer, example embodiments are not limited to this. For example, the scan register may be composed of a combination of different types of flip-flops (e.g., RS flip-flops), latch circuits, and/or logic circuits.

The first scan chain unit SC01 may include a first inverter INV1 between the eighth node N8 and the ninth node N9. The first inverter INV1 may invert the result of the eighth node N8 and output the first chain fail signal CF1.

The first priority filter PF1 may include a plurality of logical operation circuits. For example, the first priority filter PF1 may include a second AND gate AND2 and a third AND gate AND3.

One of the input terminals of the second AND gate AND2 may be connected to the eighth node N8, and another may be connected to the tenth node N10. The second AND gate AND2 may receive a default low priority parameter LWP0 as input and output a first low priority parameter LWP1. One of the input terminals of the third AND gate AND3 may receive the first chain fail signal CF1 through the ninth node N9, and another may be connected to the tenth node N10. The third AND gate AND3 may output the first scan chain output signal SCO1.

The scan register output circuit 2110 may include an AND logic operation circuit and a plurality of selection circuits. Each selection circuit may perform a selection operation in response to a switch control signal. For example, the scan register output circuit 2110 may include a fourth AND gate AND4 and first to eighth tri-state buffers TB1 to TB8. The fourth AND gate AND4 may receive the dump signal DUMP and the first scan chain output signal SCO1 and provide a tri-state switch signal TSW to the first to eighth tri-state buffers TB1 to TB8.

The first to eighth tri-state buffers TB1 to TB8 may each have three output states. For example, each tri-state buffer may output logic 1, logic 0, and high impedance/high resistance (z) according to the tri-state switch signal TSW. If the tri-state switch signal TSW is 0, high resistance (z) may be output regardless of the input. If the tri-state switch signal TSW is 1, the inverted signal of the input signal may be output. The first to eighth tri-state buffers TB1 to TB8 may output SRO[7:0].

Each scan chain unit according to various example embodiments may include a pulse gate that receives a clear pulse CP and outputs a clock signal, a plurality of scan registers that perform a scan chain operation in response to the clock signal of the pulse gate, and a priority filter that receives scan chain operation results from a plurality of scan registers and outputs a scan chain output signal.

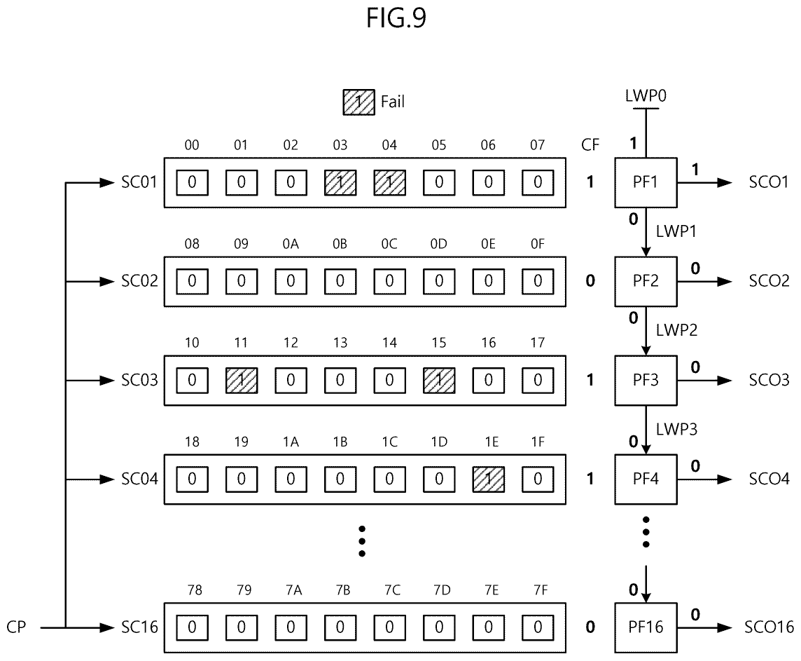

FIG. 9 is a conceptual diagram illustrating various example embodiments of a position search operation of the scan register circuit shown in FIG. 6. Referring to FIG. 9, the first scan registers 00 to 07 of the first scan chain unit SC01 may have pass/fail results of 0, 0, 0, 1, 1, 0, 0, 0, respectively. The first scan chain unit SC01 may have a first chain fail signal CF1 of logic 1. The first scan chain output signal SCO1 of the first priority filter PF1 may be logic 1.

The second scan registers 08 to 0F of the second scan chain unit SC02 may have pass/fail results of 0, 0, 0, 0, 0, 0, 0, 0, respectively. Since the second scan chain unit SC02 is all pass, the second chain fail signal CF2 may be logic 0. The second scan chain output signal SCO2 of the second priority filter PF2 may be logic 0.

The third scan registers 10 to 17 of the third scan chain unit SC03 may have pass/fail results of 0, 1, 0, 0, 0, 1, 0, 0, respectively. The third scan chain unit SC03 may have a third chain fail signal CF3 of logic 1. The third scan chain output signal SCO3 of the third priority filter PF3 may be logic 0.

The fourth scan registers 18 to 1F of the fourth scan chain unit SC04 may have pass/fail results of 0, 0, 0, 0, 0, 0, 1, 0, respectively. The fourth scan chain unit SC04 may have a fourth chain fail signal CF4 of logic 1. The fourth scan chain output signal SCO4 of the fourth priority filter PF4 may be logic 0.

In this way, the fifth to sixteenth scan chain units SC05 to SC16 may have chain fail signals of logic 0 and scan chain output signals of logic 0. In the position search operation, only the highest priority scan chain may have logic 1 through priority filters.

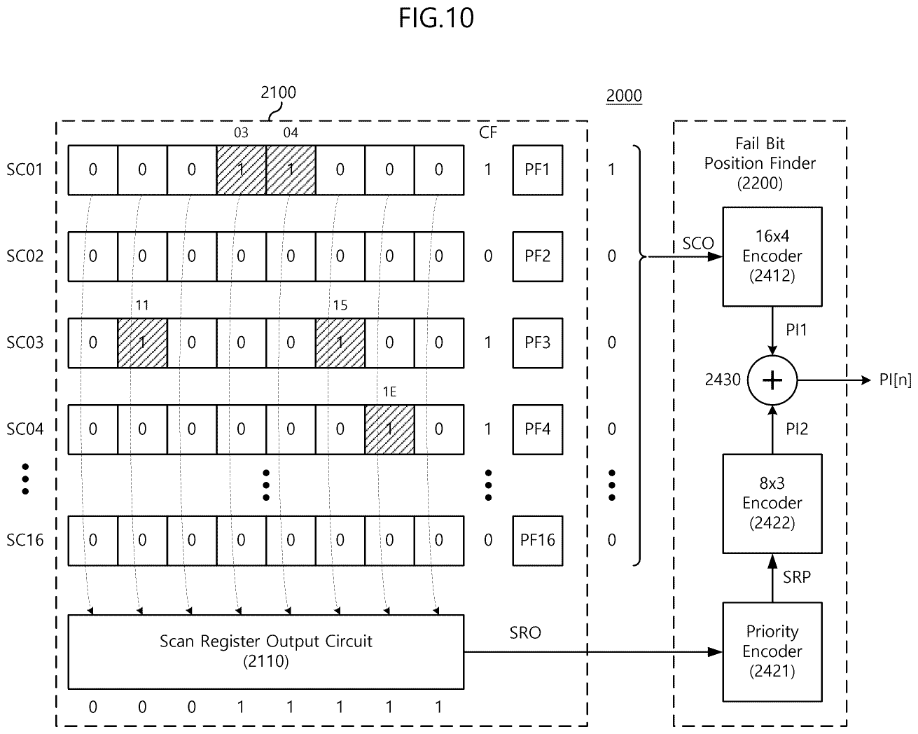

FIG. 10 is a block diagram for explaining the position search operation of the scan register circuit shown in FIG. 9. Referring to FIG. 10, the scan register circuit 2000 may include a scan register array 2100 and a fail bit position finder 2200. The fail bit position finder 2200 may receive a scan chain output signal SCO and a scan register output signal SRO from the first to sixteenth scan chain units SC01 to SC16 of the scan register array 2100. The position finder 2400 may output a position index PI[n] to detect the position of the fail bit.

The fail bit position finder 2200 may include a scan chain encoder 2412, a priority encoder 2421, a scan register encoder 2422, and an adder 2430. The scan chain encoder 2412 may be a 16×4 encoder, for example. The scan register encoder 2422 may be an 8×3 encoder, for example.

The scan register array 2100 may store the fail result value of 1 in scan registers (e.g., 03, 04, 11, 15, and 1E). Since the scan chain units (SC01, SC03, and SC04) store the fail result value of 1, the chain fail signal CF[15:0] may be 0000 0000 0000 1101.

The first to sixteenth priority filters PF1 to PF16 may receive the first to sixteenth chain fail signals CF[15:0] and may output a scan chain output signal SCO. The first to sixteenth priority filters PF1 to PF16 may make all subsequent data to 0 when the first 1 is output. The scan chain output signal SCO[15:0] may be 0000 0000 0000 0001.

The scan register array 2100 may output a scan register output signal SRO[7:0] through the scan register output circuit 2110. The scan register output signal SRO[7:0] may be 1111 1000. The priority encoder 2421 of the fail bit position finder 2200 may output the scan register priority signal SRP[7:0]. The priority encoder 2421 may make all subsequent data to 0 when the first 1 is output. The scan register priority signal SRP[7:0] may be 0000 1000.

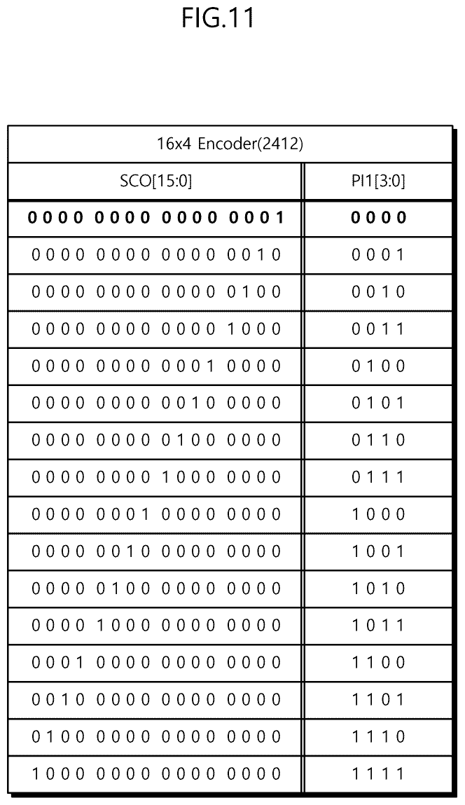

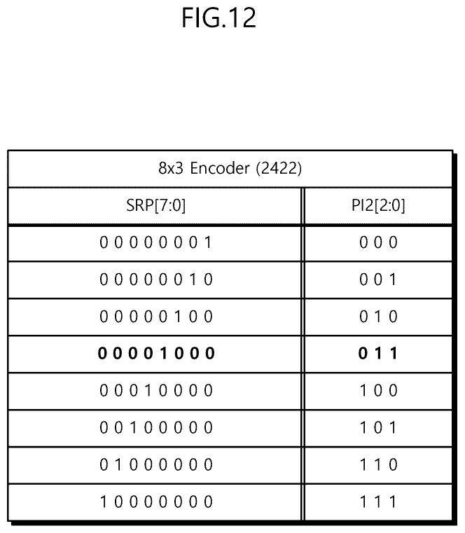

FIGS. 11 and 12 are tables for explaining the operation of the 16×4 encoder and 8×3 encoder, respectively, shown in FIG. 10. Referring to FIG. 11, the 16×4 encoder 2412 may receive the scan chain output signal SCO and output the first position index PI1. For example, if the scan chain output signal SCO[15:0] is 0000 0000 0000 0001, the first position index PI1[3:0] may be 0000.

Referring to FIG. 12, the 8×3 encoder 2422 may receive a scan register priority signal SRP and output a second position index PI2. For example, if the scan register priority signal SRP[7:0] is 0000 1000, the second position index PI2[2:0] may be 011.

Referring again to FIG. 10, the adder 2430 may receive the first position index PI1 and the second position index PI2 and output the position index signal PI[n]. For example, if the first position index PI1[3:0] is 0000 and the second position index PI2[2:0] is 011, the adder 2430 may output PI[n], that is, 0000011.

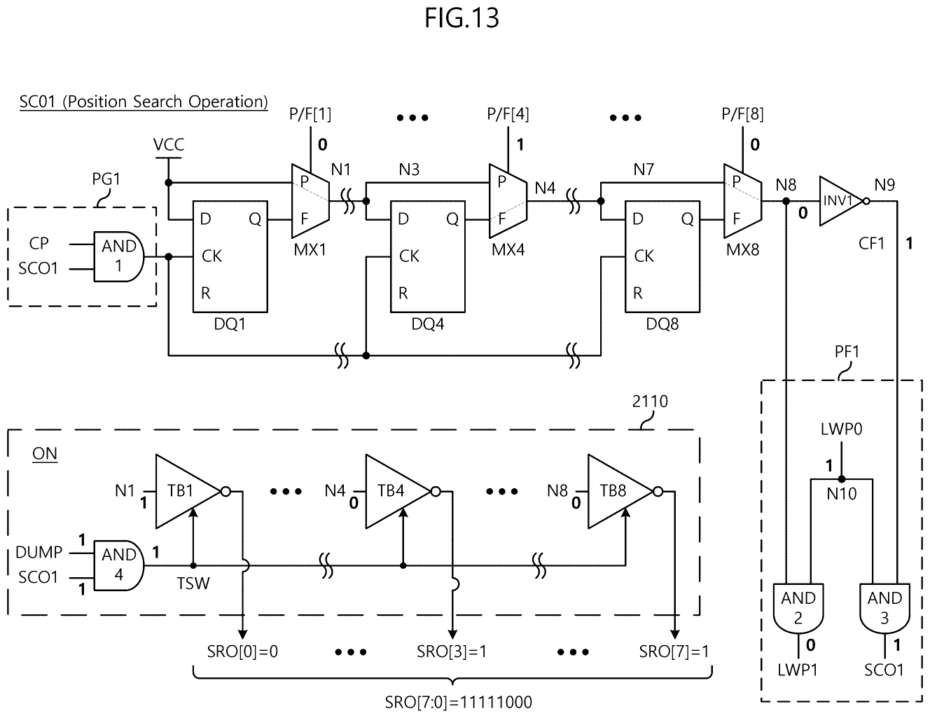

FIG. 13 is a circuit diagram illustrating various example embodiments of the position search operation of the first scan chain unit shown in FIG. 10. Referring to FIG. 13, the first pass/fail result P/F[1] is 0, the fourth pass/fail result P/F[4] is 1, and the eighth pass/fail result P/F[8] is 0. The first to eighth flip-flops DQ1 to DQ8 may all be initialized by a reset signal provided to the R terminal.

If the first pass/fail result P/F[1] is logic 0, the P terminal of the first multiplexer MX1 may be connected to the first node N1. The first node N1 may be logic 1 because it is connected to the power terminal. If the fourth pass/fail result P/F[4] is logic 1, the F terminal of the fourth multiplexer MX4 may be connected to the fourth node N4. Since the fourth flip-flop DQ4 may be initialized by a reset signal, the fourth node N4 may be logic 0. If the eighth pass/fail result P/F[8] is 0, the P terminal of the eighth multiplexer MX8 may be connected to the seventh node N7. The eighth node N8 may be logic 0.

If the dump signal DUMP is 1 and the first scan chain output signal SCO1 is 1, the tri-state switch signal TSW is 1. If the tri-state switch signal TSW is 1, the output of the first to eighth tri-state buffers TB1 to TB8 may be the inverted value of the input. For example, since the first node N1 is 1, SRO[0] may be 0. Since the fourth node N4 is 0, SRO[3] may be 1. Since the eighth node N8 is 0, SRO[7] may be 1. The scan register output signal SRO[7:0] of the scan register output circuit 2110 may be 1111 1000.

If the default low priority parameter LWP0 is 1, the 10th node N10 may be logic 1. Therefore, the output of the third AND gate AND3 may have the same value as the logic value of the ninth node N9. That is, the first scan chain output signal SCO1 may be equal to the first chain fail signal CF1. If the first chain fail signal CF1 is 1, the first scan chain output signal SCO1 may be 1.

If the default low priority parameter LWP0 is 1, the first low priority parameter LWP1 may be equal to the logical value of the eighth node N8. If the eighth node N8 is logic 0, the first low priority parameter LWP1 may be logic 0.

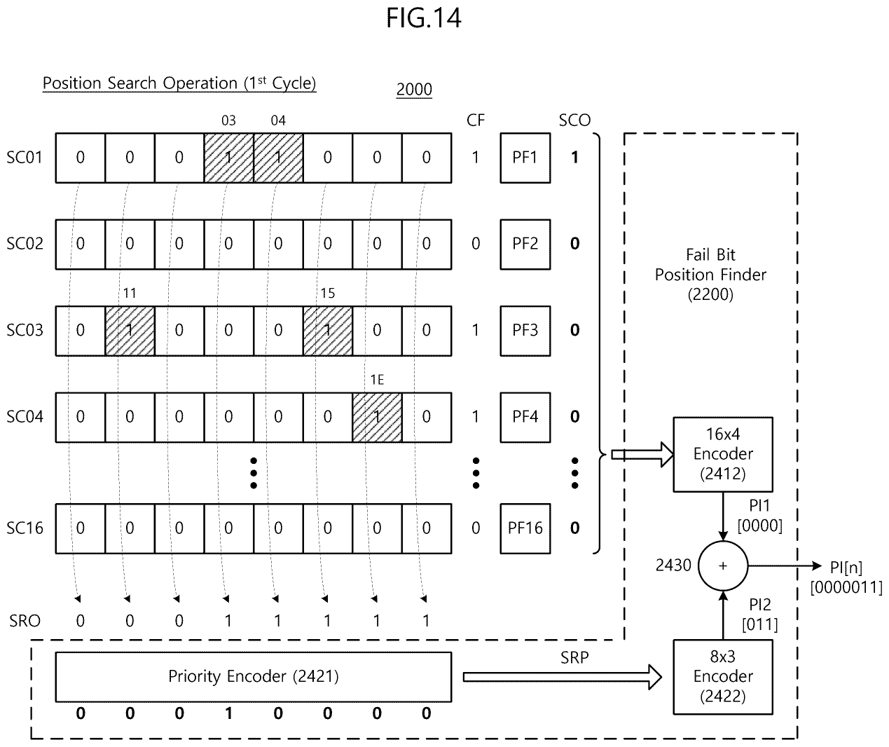

FIGS. 14 to 18 are diagrams illustrating various example embodiments of the position search operation during the first to fifth cycles of the scan register circuit shown in FIG. 10. Referring to FIGS. 14 to 18, the fail bit position finder 2200 may include a 16×4 bit encoder 2412, a priority encoder 2421, an 8×3 encoder 2422, and an adder 2430.

Referring to FIG. 14, in the first cycle of the position search operation, the fail result value of 1 may be stored in the scan registers 03 and 04 of the first scan chain unit SC01, and the first chain fail signal CF1 may be 1. The pass result value of 0 may be stored in the scan registers 08 to 0F of the second scan chain unit SC02, and the second chain fail signal CF2 may be 0. The fail result value of 1 may be stored in the scan registers 11 and 15 of the third scan chain unit SC03, and the third chain fail signal CF3 may be 1. The fail result value of 1 may be stored in the scan register 1E of the fourth scan chain unit SC04, and the fourth chain fail signal CF4 may be 1. All of the 5th to 16th chain fail signals CF5 to CF16 may be 0.

In the first cycle of the position search operation, the chain fail signal CF[15:0] may be 0000 0000 0000 1101. The priority filters PF1 to PF16 may receive the chain fail signal CF[15:0] and output a scan chain output signal SCO[15:0]. The scan chain output signal SCO[15:0] may be 0000 0000 0000 0001.

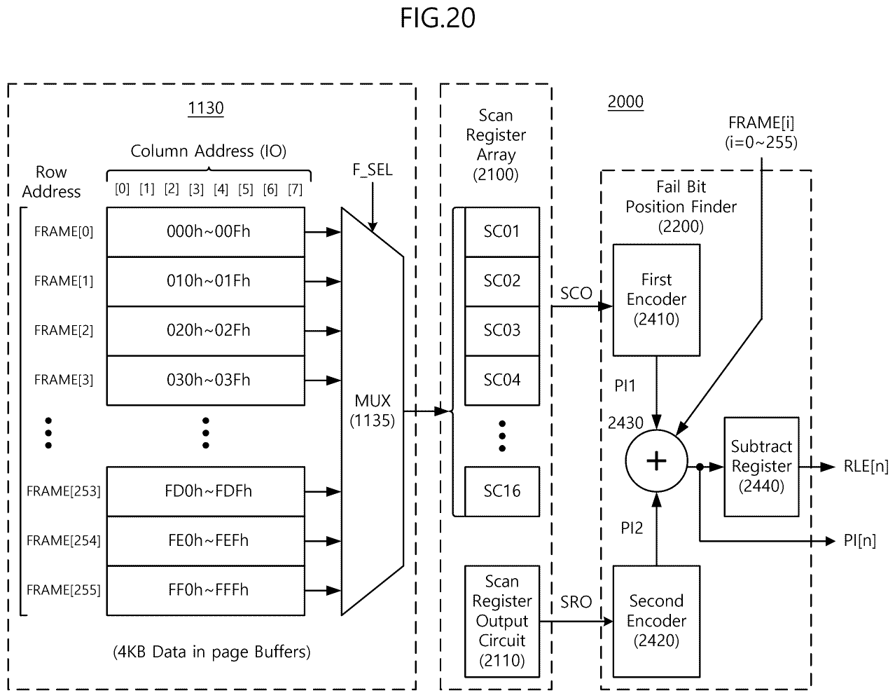

The scan register output circuit 2110 (see FIG. 20) may output a scan register output signal SRO[7:0]. The scan register output signal SRO[7:0] may be 1111 1000. The priority encoder 2421 of the fail bit position finder 2200 may output a scan register priority signal SRP[7:0]. The scan register priority signal SRP[7:0] may be 0000 1000.

The 16×4 encoder 2412 may receive a scan chain output signal SCO[15:0] and output a first position index PI1. If the scan chain output signal SCO[15:0] is 0000 0000 0000 0001, the first position index PI1[3:0] may be 0000. The 8×3 encoder 2422 may receive a scan register priority signal SRP and output a second position index PI2. If the scan register priority signal SRP[7:0] is 0000 1000, the second position index PI2[2:0] may be 011.

The adder 2430 may receive a first position index PI1 and a second position index PI2 and output a position index signal PI[n]. If the first position index PI1[3:0] is 0000 and the second position index PI2[2:0] is 011, the adder 2430 may output the position index signal PI[n]. The position index signal PI[n] may be 0000011. The PI[n] may be a position index indicating the position of scan register 03 of the scan register array 2100.

The position of the scan register 03 may be a location where both the scan chain output signal SCO and the scan register priority signal SRP are 1. When the scan operation proceeds from the scan register 00 to the scan register 7F, the scan register 03 may store the first fail bit. The scan register circuit 2000 may output a position index PI[n] indicating the position of the scan register 03 in the first cycle of the position search operation.

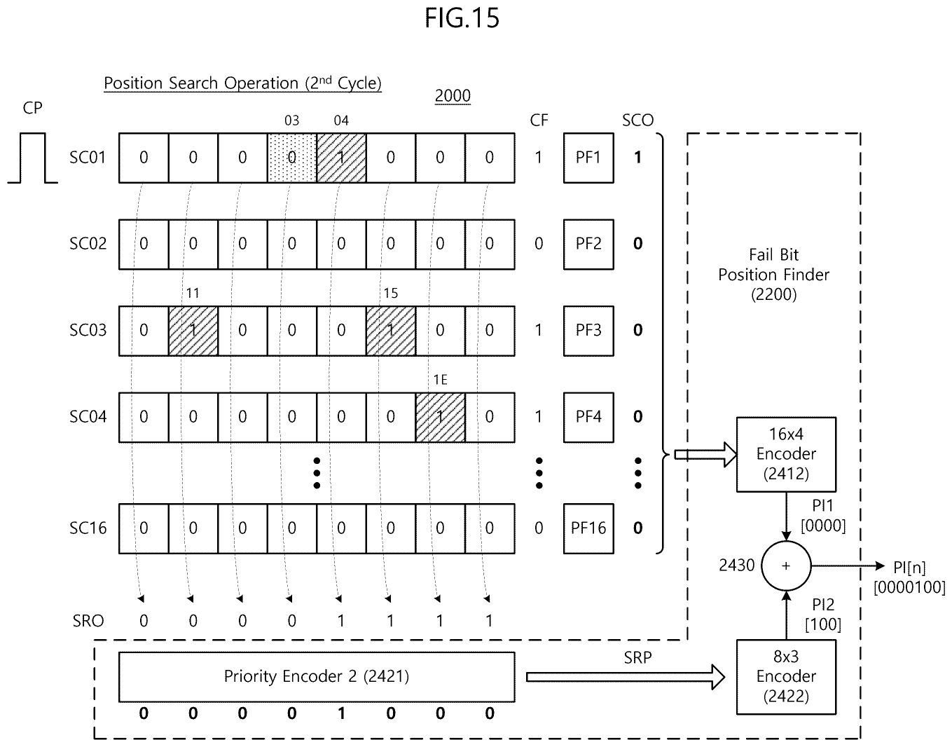

Referring to FIG. 15, when the clear pulse CP is applied in the second cycle of the position search operation, the scan register 03 of the first scan chain unit SC01 may be cleared, and the fail result value of 1 stored in the scan register 04 may be maintained. The first chain fail signal CF1 may be 1. The second chain fail signal CF2 may be 0, and the third and fourth chain fail signals CF3 and CF4 may be 1. All of the 5th to 16th chain fail signals CF5 to CF16 may be 0.

In the second cycle of the position search operation, the chain fail signal CF[15:0] may be 0000 0000 0000 1101. The scan chain output signal SCO[15:0] may be 0000 0000 0000 0001. The scan register output signal SRO[7:0] may be 1111 0000. The scan register priority signal SRP[7:0] may be 0001 0000.

If the scan chain output signal SCO[15:0] is 0000 0000 0000 0001, the first position index PI1[3:0] may be 0000. If the scan register priority signal SRP[7:0] is 0001 0000, the second position index PI2[2:0] may be 100. If the first position index PI1[3:0] is 0000 and the second position index PI2[2:0] is 100, the position index signal may be PI[n]=[0000100]. The position index signal PI[n] may indicate the position of the scan register 04.

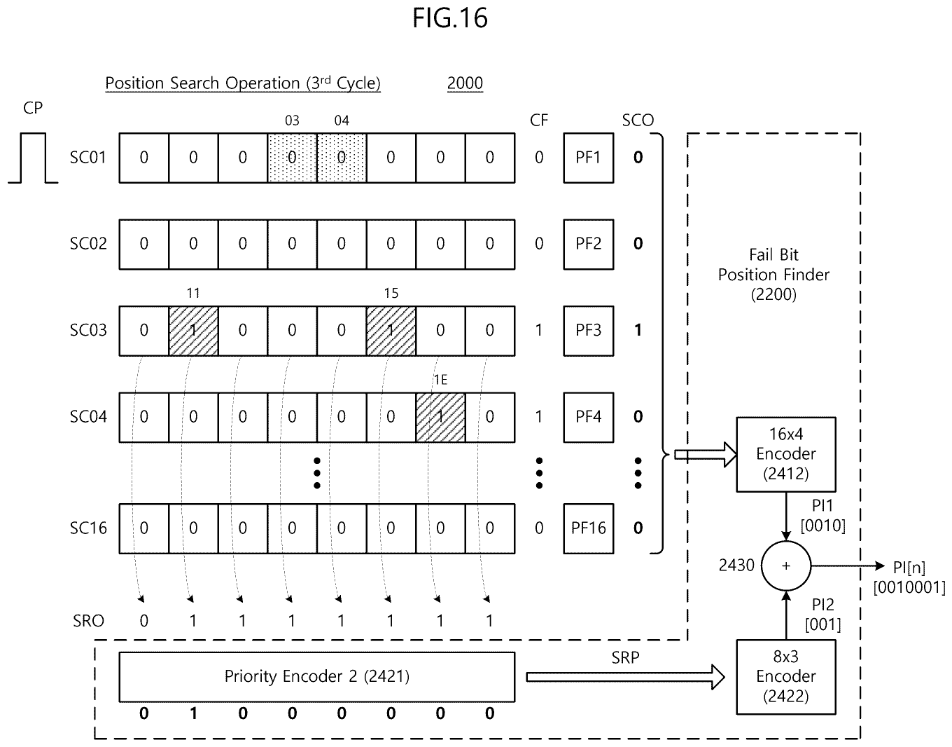

Referring to FIG. 16, when the clear pulse CP is applied in the third cycle of the position search operation, the scan register 04 of the first scan chain unit SC01 may be cleared, and the first chain fail signal CF1 may be 0. The second chain fail signal CF2 may be 0, and the third and fourth chain fail signals CF3 and CF4 may be 1. All of the 5th to 16th chain fail signals CF5 to CF16 may be 0.

In the third cycle of the position search operation, the chain fail signal CF[15:0] may be 0000 0000 0000 1100. The scan chain output signal SCO[15:0] may be 0000 0000 0000 0100. The scan register output signal SRO[7:0] is It could be 1111 1110. The scan register priority signal SRP[7:0] may be 0000 0010.

If the scan chain output signal SCO[15:0] is 0000 0000 0000 0100, the first position index PI1[3:0] may be 0010. If the scan register priority signal SRP[7:0] is 0000 0010, the second position index PI2[2:0] may be 001. If the first position index PI1[3:0] is 0010 and the second position index PI2[2:0] is 001, the position index signal may be PI[n]=[0010001]. The position index signal PI[n]=[0010001] may indicate the position of the scan register 11.

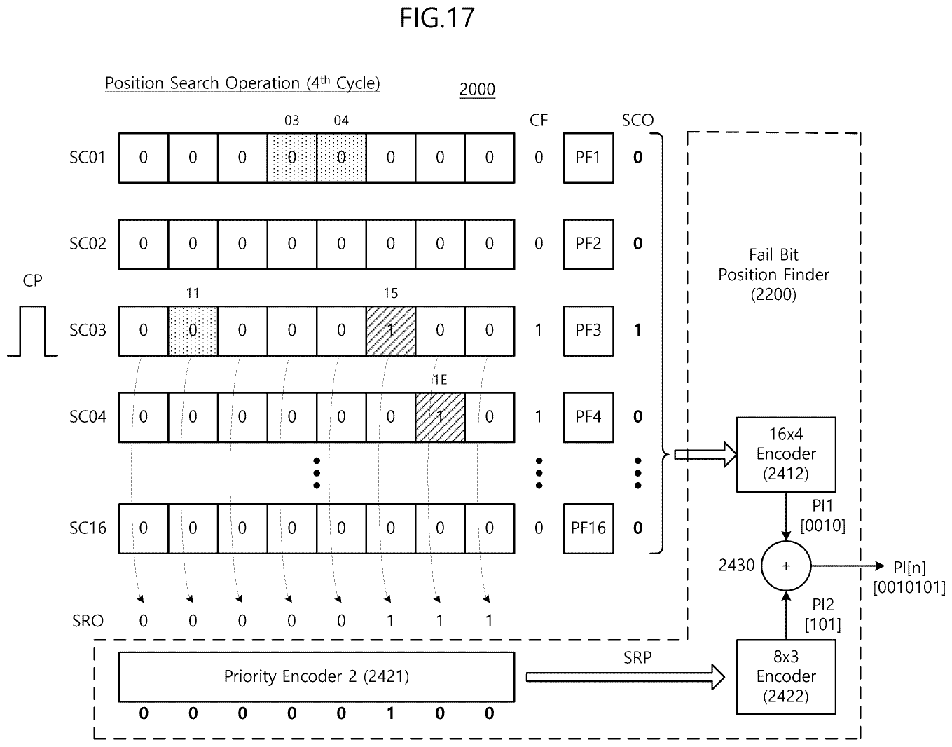

Referring to FIG. 17, when the clear pulse CP is applied in the fourth cycle of the position search operation, the scan register 11 of the third scan chain unit SC03 may be cleared, and the third chain fail signal CF3 may be 1. The fourth chain fail signal CF4 may be 1. All of the 5th to 16th chain fail signals CF5 to CF16 may be 0.

In the fourth cycle of the position search operation, the chain fail signal CF[15:0] may be 0000 0000 0000 1100. The scan chain output signal SCO[15:0] may be 0000 0000 0000 0100. The scan register output signal SRO[7:0] may be 1110 0000. The scan register priority signal SRP[7:0] may be 0010 0000.

If the scan chain output signal SCO[15:0] is 0000 0000 0000 0100, the first position index PI1[3:0] may be 0010. If the scan register priority signal SRP[7:0] is 0010 0000, the second position index PI2[2:0] may be 101. If the first position index PI1[3:0] is 0010 and the second position index PI2[2:0] is 101, the position index signal may be PI[n]=[0010101]. The position index signal PI[n]=[0010101] may indicate the position of the scan register 15.

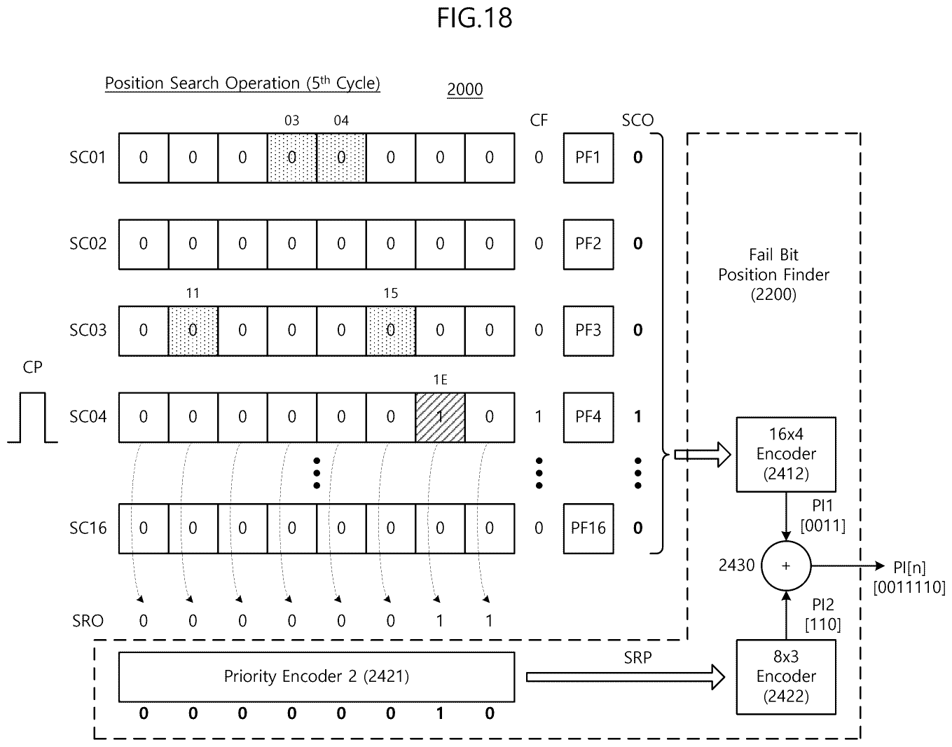

Referring to FIG. 18, when the clear pulse CP is applied in the fifth cycle of the position search operation, the scan register 15 of the third scan chain unit SC03 may be cleared, and the third chain fail signal CF3 may be 0. The fourth chain fail signal CF4 may be 1. All of the 5th to 16th chain fail signals CF5 to CF16 may be 0.

In the fifth cycle of the position search operation, the chain fail signal CF[15:0] may be 0000 0000 0000 1000. The scan chain output signal SCO[15:0] may be 0000 0000 0000 1000. The scan register output signal SRO[7:0] may be 1100 0000. The scan register priority signal SRP[7:0] may be 0100 0000.

If the scan chain output signal SCP [15:0] is 0000 0000 0000 1000, the first position index PI1[3:0] may be 0011. If the scan register priority signal SRP[7:0] is 0100 0000, the second position index PI2[2:0] may be 110. If the first position index PI1[3:0] is 0011 and the second position index PI2[2:0] is 110, the position index signal may be PI[n]=[0011110]. The position index signal PI[n]=[0011110] may indicate the position of the scan register 1E.

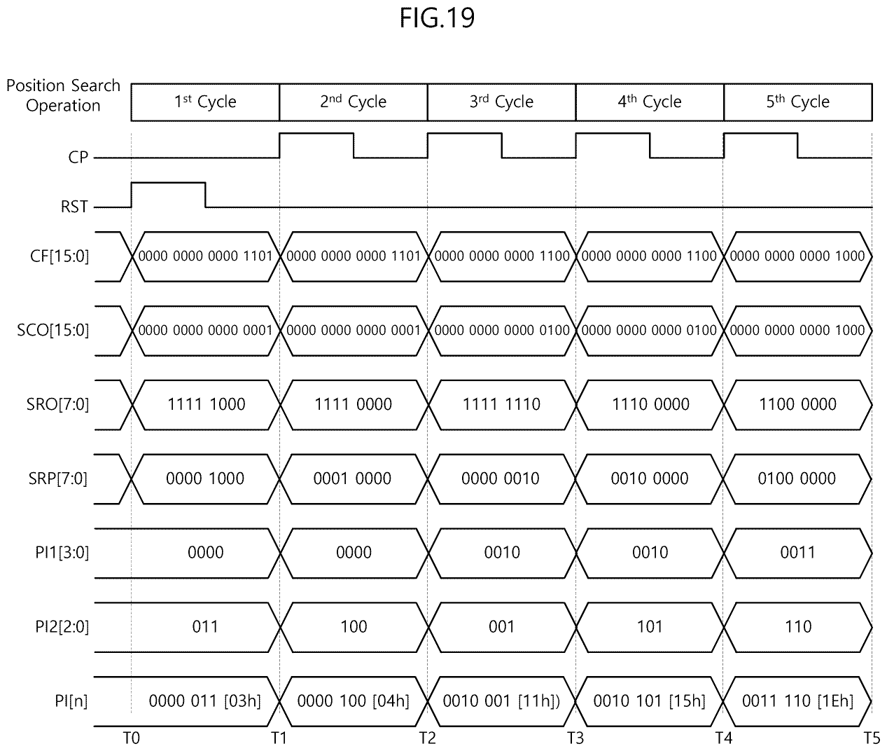

FIG. 19 is a timing diagram illustrating the position search operation during the first to fifth cycles of the scan register circuit shown in FIG. 10. In the first cycle of the position search operation, the chain fail signal CF[15:0] may be 0000 0000 0000 1101. The scan chain output signal SCO[15:0] may be 0000 0000 0000 0001. The scan register output signal SRO[7:0] may be 1111 1000. The scan register priority signal SRP[7:0] may be 0000 1000. The first position index PI1[3:0] may be 0000. The second position index PI2[2:0] may be 011. The position index signal PI[n]=[0000011] may indicate the position of the scan register 03.

In the second cycle of the position search operation, the chain fail signal CF[15:0] may be 0000 0000 0000 1101. The scan chain output signal SCO[15:0] may be 0000 0000 0000 0001. The scan register output signal SRO[7:0] may be 1111 0000. The scan register priority signal SRP[7:0] may be 0001 0000. The first position index PI1[3:0] may be 0000. The second position index PI2[2:0] may be 100. The position index signal PI[n]=[0000100] may indicate the position of the scan register 04.

In the third cycle of the position search operation, the chain fail signal CF[15:0] may be 0000 0000 0000 1100. The scan chain output signal SCO[15:0] may be 0000 0000 0000 0100. The scan register output signal (SRO[7:0] may be 1111 1110. The scan register priority signal SRP[7:0] may be 0000 0010. The first position index PI1[3:0] may be 0010. The second position index PI2[2:0] may be 001. The position index signal PI[n]=[0010001] may indicate the position of the scan register 11.

In the fourth cycle of the position search operation, the chain fail signal CF[15:0] may be 0000 0000 0000 1100. The scan chain output signal SCO[15:0] may be 0000 0000 0000 0100. The scan register output signal SRO[7:0] may be 1110 0000. The scan register priority signal SRP[7:0] may be 0010 0000. The first position index PI1[3:0] may be 0010. The second position index PI2[2:0] may be 101. The position index signal PI[n]=[0010101] may indicate the position of the scan register 15.

In the fifth cycle of the position search operation, the chain fail signal CF[15:0] may be 0000 0000 0000 1000. The scan chain output signal SCO[15:0] may be 0000 0000 0000 1000. The scan register output signal SRO[7:0] may be 1100 0000. The scan register priority signal SRP[7:0] may be 0100 0000. The first position index PI1[3:0] may be 0011. The second position index PI2[2:0] may be 110. The position index signal PI[n]=[0011110] may indicate the position of the scan register 1E.

FIGS. 20 to 22 are block diagrams for explaining an embodiment of the position search operation of the scan register circuit shown in FIG. 2. Referring to FIG. 20, the scan register circuit 2000 may include a scan register array 2100 and a fail bit position finder 2200.

The scan register array 2100 may receive a plurality of frame data from the page buffer circuit 1130. For example, the page buffer circuit 1130 may include 256 frame data (FRAME [i]; i=0 to 255).

Each frame data may be sequentially loaded into scan chain units of the scan register array 2100 through a multiplexer (MUX, 1135). For example, each frame data may be sequentially loaded into the first to sixteenth scan chain units (SC01 to SC16). The multiplexer 1135 may select one frame by using the frame selection signal F_SEL provided from the control logic 1160.

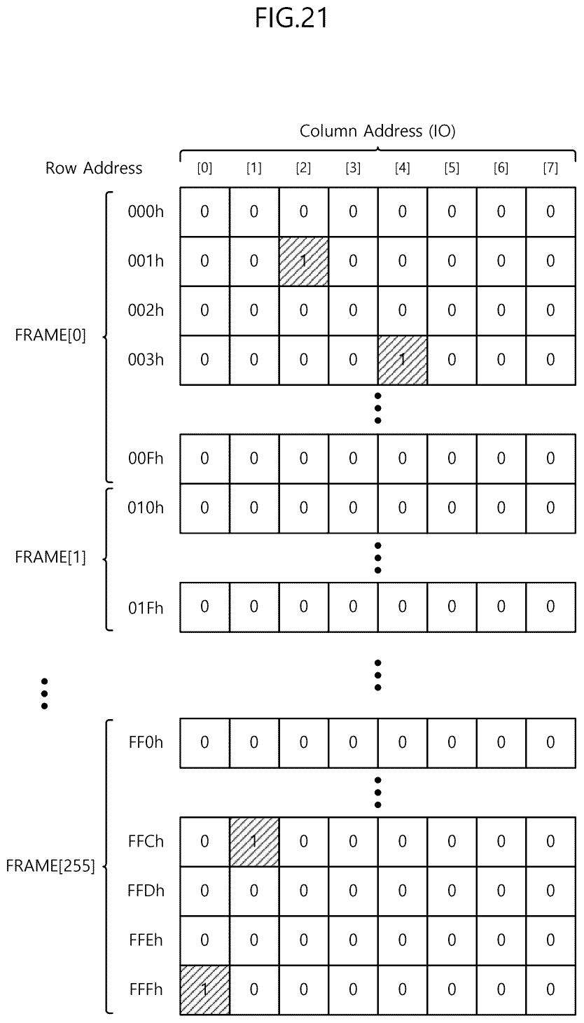

Referring to FIG. 21, FRAME[0] may be composed of 16 row addresses (000h to 00Fh). FRAME[1] may be composed of 16 row addresses (010h to 01Fh), and FRAME[255] may be composed of 16 row addresses (FF0h to FFFh).

Each scan chain unit of the scan register array 2100 may include a plurality of scan registers. For example, each scan chain unit may include eight scan registers. Each scan register may store data representing the pass/fail result. The scan register array 2100 may indicate the position of the fail bit using a scan chain unit address and a column address. The row address may include frame addresses and scan chain unit addresses. The column address may be composed of IO addresses.

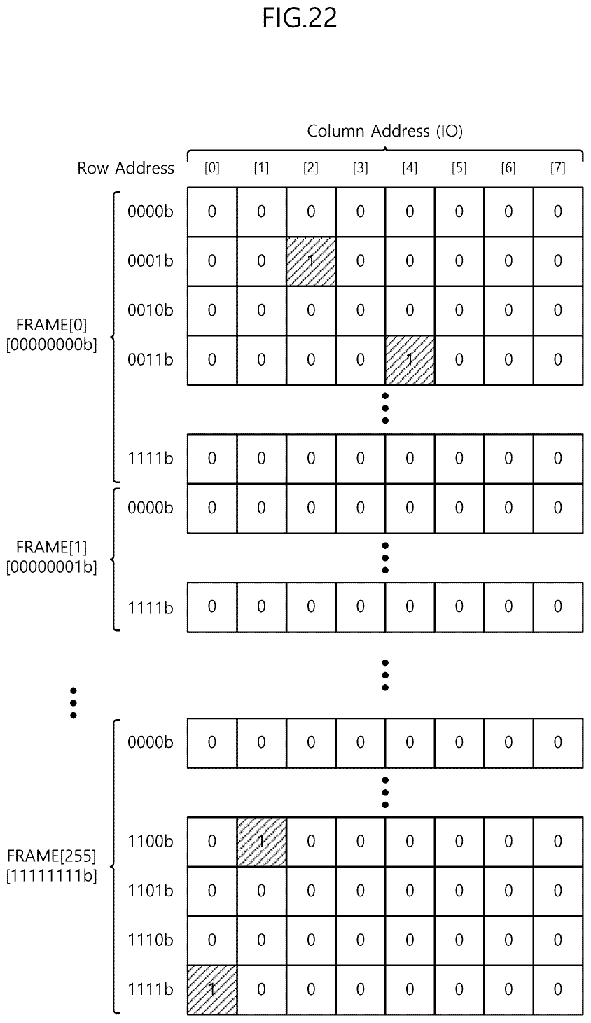

Referring to FIG. 22, The number of frames is 256. The frame address may be expressed as an 8-bit address. Each frame may consist of 16 scan chain units. The scan chain unit address may be expressed as a 4-bit address. The number of IOs is 8. The IO address may be expressed as a 3-bit address; example embodiments are not limited thereto.

In FIGS. 21 and 22, the position of the first fail bit may be indicated using 001h of FRAME[0] and IO[2]. The position of the second fail bit may be expressed using 003h of FRAME[0] and IO[4]. The position of the third fail bit may be expressed using FFCh of FRAME[255] and IO[1]. The position of the fourth fail bit may be expressed using FFFh of FRAME[255] and IO[0].

Referring to FIG. 20, the fail bit position finder 2200 may include a first encoder 2410, a second encoder 2420, an adder 2430, and a subtract register 2440. The first encoder 2410 may include a scan chain encoder. The second encoder 2420 may include a priority encoder and a scan register encoder. The scan chain encoder may be a 16×4 encoder, for example. The scan register encoder may be an 8×3 encoder as an example.

The first encoder 2410 may receive the scan chain output signal SCO for each frame and output the first position index PI1. The first position index PI1 may be a 4-bit address. The second encoder 2420 may receive a scan register output signal SRO in each IO unit and output a second position index PI2. The second position index PI2 may be a 3-bit address.

The adder 2430 may receive the first position index PI1, the second position index PI2, and the frame address (FRAME[i]; i=0˜255), and output a position index signal PI[n]. The frame address may be provided from control logic 1160 (see FIG. 6). The adder 2430 may output a 16-bit position index signal PI[n] using the end flag, frame address, first position index address, and second position index address.

The subtract register 2440 may receive a position index signal from the adder 2430 and output a run-length encoding signal RLE. The run-length encoding technology is or includes a lossless data compression method that encodes data that appears repeatedly in succession and the number of repetitions thereof into corresponding values. The RLE signal may indicate repeated data 0 and its number through the difference between the current position index signal PI[n] and the previous position index signal PI[n−1].

The scan register circuit 2000 may provide the position index signal PI[n] and the RLE signal to the memory controller 1200 (see FIG. 1). The memory controller 1200 may easily and effectively find the fail bit position using the position index signal PI[n] and the RLE signal.

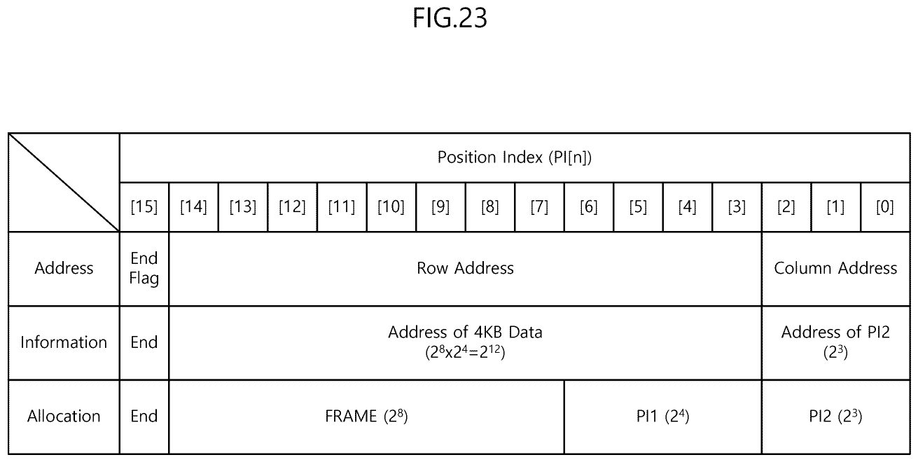

FIG. 23 is a diagram illustrating the position index signal of the scan register circuit shown in FIG. 20. Referring to FIG. 23, the position index signal PI[n] may be expressed in 16 bits. The lower 3 bits ([0] to [2]) of the position index signal PI[n] may be a column address and may be configured as the address of the second position index PI2. The next 12 bits ([3] to [14]) of the position index signal PI[n] may be a row address and may be configured as the address of the first position index (PI1) and a frame address.

The address of the first position index PI1 may be composed of 4 bits, and the frame address may be composed of 8 bits. The number of frames are 256. Each frame may consist of 16 scan chain units. Each scan chain unit may include 8 scan registers. And each scan register may store data indicating pass or fail.

Therefore, 4 KB of data may be stored in the frames of FIG. 20. Here, 1 Byte may be 8 bits. The row address of 4 KB of data may be expressed in 12 bits. Among the 12 bits, 4 bits may be expressed as the address of the first position index PI1, and the remaining 8 bits may be expressed as the frame address.

The last 1 bit of the position index signal PI[n] may represent an end flag. The end flag may be expressed as 1 if the last data of 4 KB data is a fail bit. Therefore, the position index signal PI[n] may be expressed as a 1-bit end flag, an 8-bit frame, a 4-bit first position index, and a 3-bit second position index.

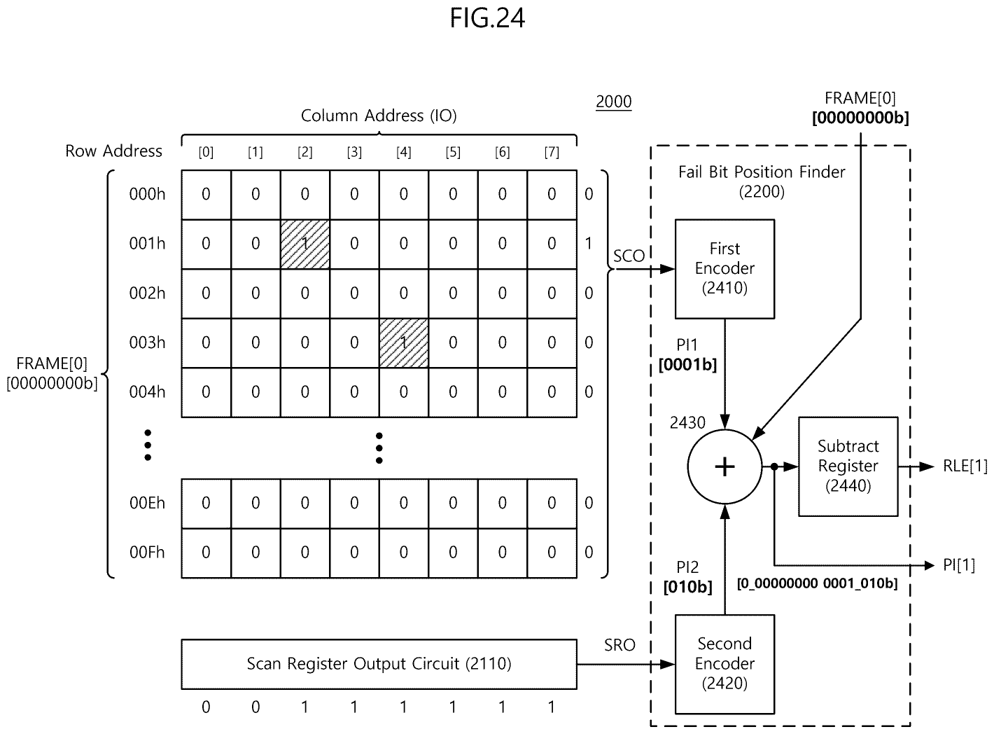

FIGS. 24 to 29 are block diagrams for explaining an operation of calculating position index signals and RLE signals of first to fourth fail bits.

The scan register circuit 2000 may include a scan register array 2100 and a fail bit position finder 2200. Referring to FIG. 24, the first fail bit may be stored in the scan register located in the 001h scan chain unit of FRAME[0] and IO[2]. The scan register circuit 2000 may output a position index signal PI[1] indicating the position of the first fail bit through a fail bit scan operation.

The chain fail signal CF[15:0] may be 0000 0000 0000 1010. The scan chain output signal SCO[15:0] may be 0000 0000 0000 0010. The first encoder 2410 may receive the scan chain output signal SCO[15:0], 0000 0000 0000 0010 and output the first position index PI1 through a 16×4 encoder. Referring to the diagram of FIG. 11, the first position index PI1 may be 0001b.

The scan register output signal SRO may be 1111 1100. The second encoder 2420 may generate 0000 0100 through a priority encoder and output the second position index PI2 through an 8×3 encoder. Referring to the diagram of FIG. 12, the second position index PI2 may be 010b.

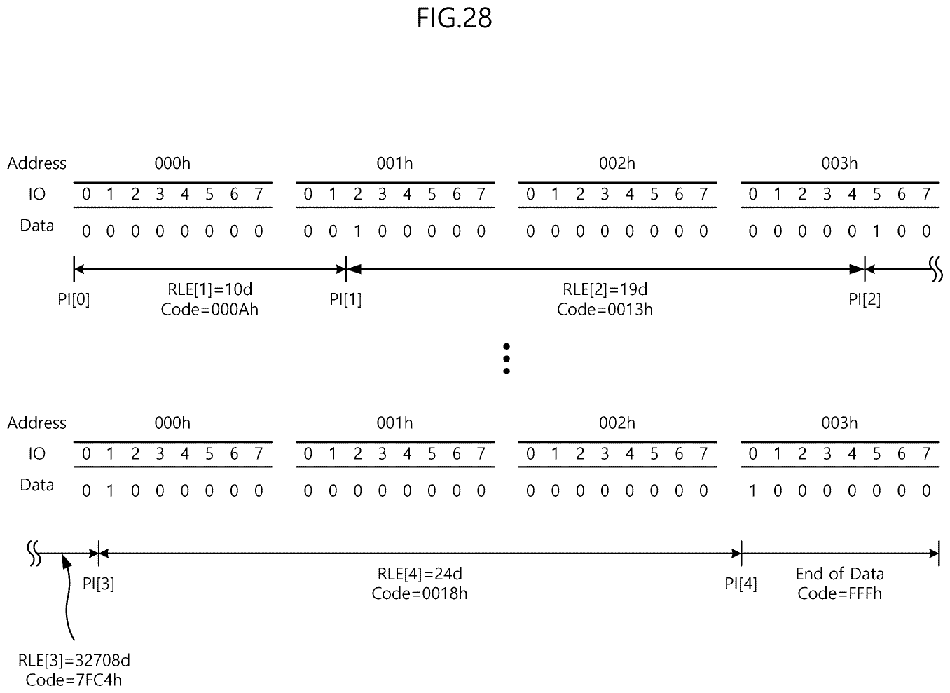

The address of FRAME[0] is 0000 0000b, and the end flag is 0b. The adder 2430 may output a position index signal PI[1] using the end flag, frame address, first position index, and second position index. The position index signal PI[1] may be 0_00000000_0001_010b. The subtract register 2440 may output RLE[1] using the difference between PI[1] and PI[0]. Referring to FIG. 28, RLE[1] may be PI[1]-PI[0], which is 10d in decimal code and 000Ah in hex code. RLE[1] may be a compressed representation of the number of data 0s repeated up to the first fail bit.

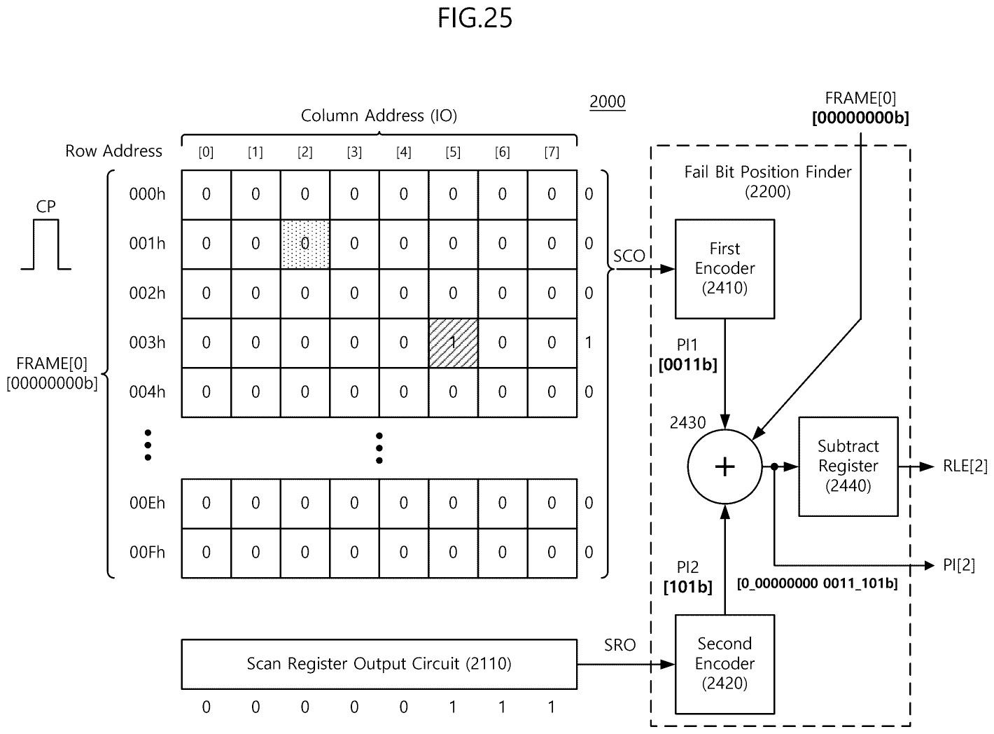

Referring to FIG. 25, when a clear pulse is applied, the first fail bit may be changed to 0. The second fail bit may be stored in the scan register located in the 003h scan chain unit of FRAME[0] and IO[5]. The scan register circuit 2000 may output a position index signal PI[2] indicating the position of the second fail bit through a fail bit scan operation.

The scan chain output signal SCO may be 0000 0000 0000 1000. The first encoder 2410 may receive the scan chain output signal SCO, 0000 0000 0000 1000 and output the first position index PI1 through a 16×4 encoder. Referring to the diagram of FIG. 11, the first position index PI1 may be 0011b.

The scan register output signal SRO may be 1110 0000. The second encoder 2420 may generate 0010 0000 through a second priority encoder and output a second position index PI2 through an 8×3 encoder. Referring to the diagram of FIG. 12, the second position index PI2 may be 101b.

The address of FRAME[0] may be 0000 0000b, and the end flag is 0b. The adder 2430 may output a position index signal PI[2] using the end flag, frame address, first position index, and second position index. The position index signal PI[2] may be 0_00000000_0011_101b. The subtract register 2440 may output RLE[2] using the difference between PI[2] and PI[1]. Referring to FIG. 28, RLE[2] may be PI[2]-PI[1], which is 19d in decimal code and 0013h in hex code. RLE[2] may be a compressed representation of the number of repeated data 0s from the first fail bit to the second fail bit.

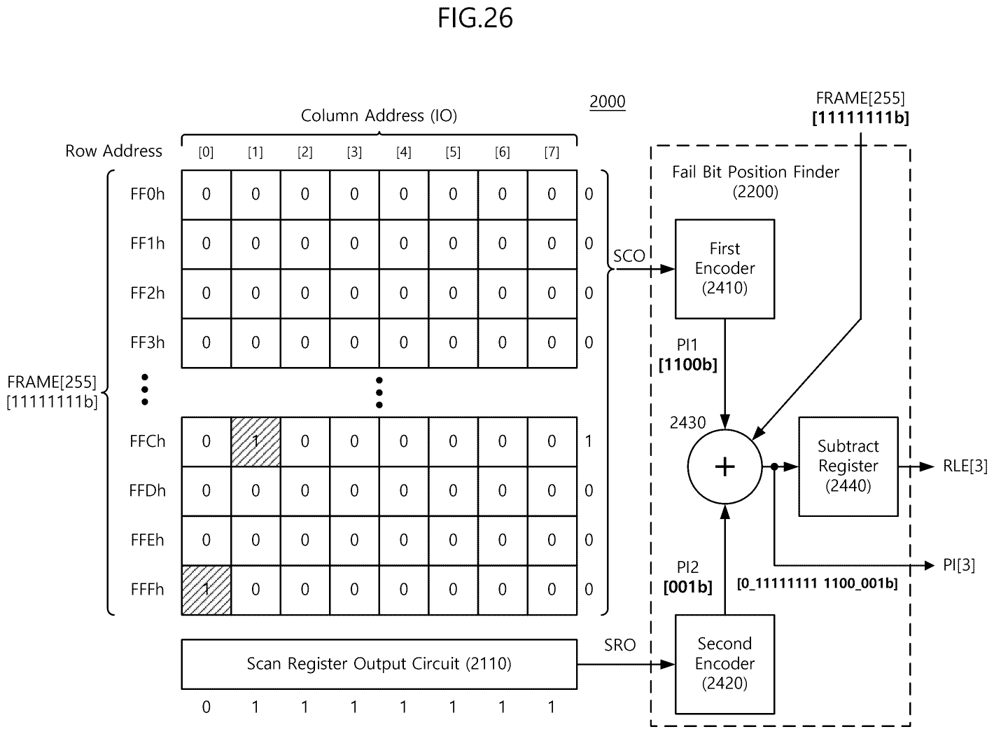

Referring to FIG. 26, when a clear pulse is applied, the second fail bit may be changed to 0. The third fail bit may be stored in the scan register located in the FFCh scan chain unit of FRAME[255] and IO[1]. The scan register circuit 2000 may output a position index signal PI[3] indicating the position of the third fail bit through a fail bit scan operation.

The chain fail signal CF[15:0] may be 1001 0000 0000 0000. The scan chain output signal SCO[15:0] may be 0001 0000 0000 0000. The first encoder 2410 may receive the scan chain output signal SCO[15:0], 0001 0000 0000 0000 through the first priority encoder and output the first position index PI1 through the 16×4 encoder. Referring to the diagram of FIG. 11, the first position index PI1 may be 1100b.

The scan register output signal SRO may be 1111 1110. The second encoder 2420 may generate 0000 0010 through a priority encoder and output the second position index PI2 through an 8×3 encoder. Referring to the diagram of FIG. 12, the second position index PI2 may be 001b.

The address of FRAME[255] is 1111 1111b, and the end flag is 0b. The adder 2430 may output a position index signal PI[3] using the end flag, frame address, first position index, and second position index. The position index signal PI[3] may be 0_11111111_1100_001b. The subtract register 2440 may output RLE[3] using the difference between PI[3] and PI[2]. Referring to FIG. 28, RLE[3] is PI[3]-PI[2], which is 32708d in decimal code and 7FC4h in hex code. RLE[3] is a compressed representation of the number of repeated data 0s from the 2nd fail bit to the 3rd fail bit.

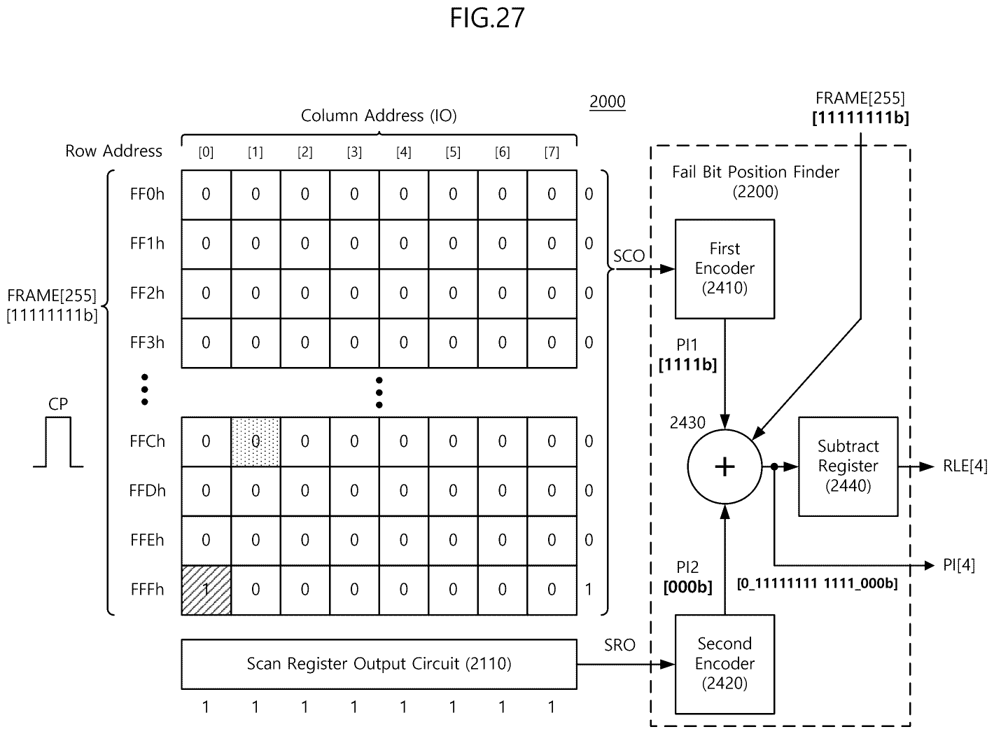

Referring to FIG. 27, when a clear pulse is applied, the third fail bit may be changed to 0. The fourth fail bit may be stored in the scan register located in the FFFh scan chain unit of FRAME[255] and IO[0]. The scan register circuit 2000 may output a position index signal PI[4] indicating the position of the fourth fail bit through a fail bit scan operation.

The scan chain output signal SCO may be 1000 0000 0000 0000. The first encoder 2410 may receive a scan chain output signal SCO, 1000 0000 0000 0000 and output a first position index PI1 through a 16×4 encoder. Referring to the diagram of FIG. 11, the first position index PI1 may be 1111b.

The scan register output signal SRO may be 1111 1111. The second encoder 2420 may generate 0000 0001 through a second priority encoder and output a second position index PI2 through an 8×3 encoder. Referring to the diagram of FIG. 12, the second position index PI2 may be 000b.

The address of FRAME[255] is 1111 1111b, and the end flag is 0b. The adder 2430 may output a position index signal PI[4] using the end flag, frame address, first position index, and second position index. The position index signal PI[4] may be 0_11111111_1111_000b. The subtract register 2440 may output RLE[4] using the difference between PI[4] and PI[3]. Referring to FIG. 28, RLE[4] is PI[4]-PI[3], which is 24d in decimal code and 0018h in hex code. RLE[4] may compress and represent the number of repeated data 0s from the third fail bit to the fourth fail bit.

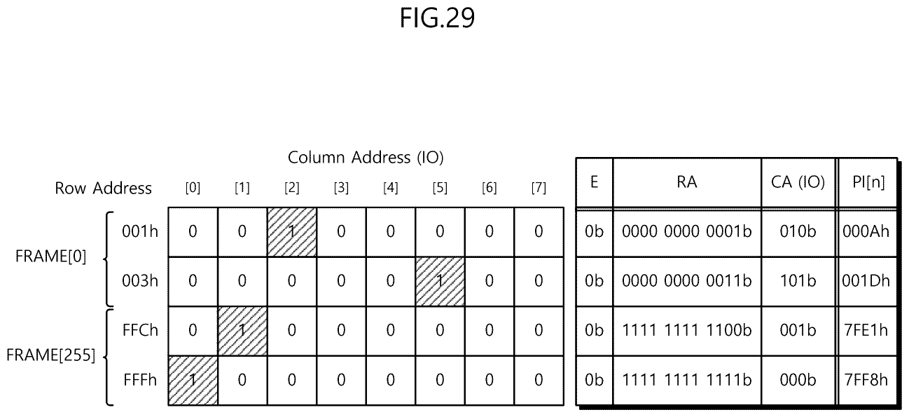

If a fail bit scan operation is performed after the fourth fail bit, the end flag may be 1 because there are no more fail bits. Referring to FIG. 29, the first to fourth fail bits may be expressed as 000Ah, 001Dh, 7FE1h, and 7FF8h, respectively, in hex code.

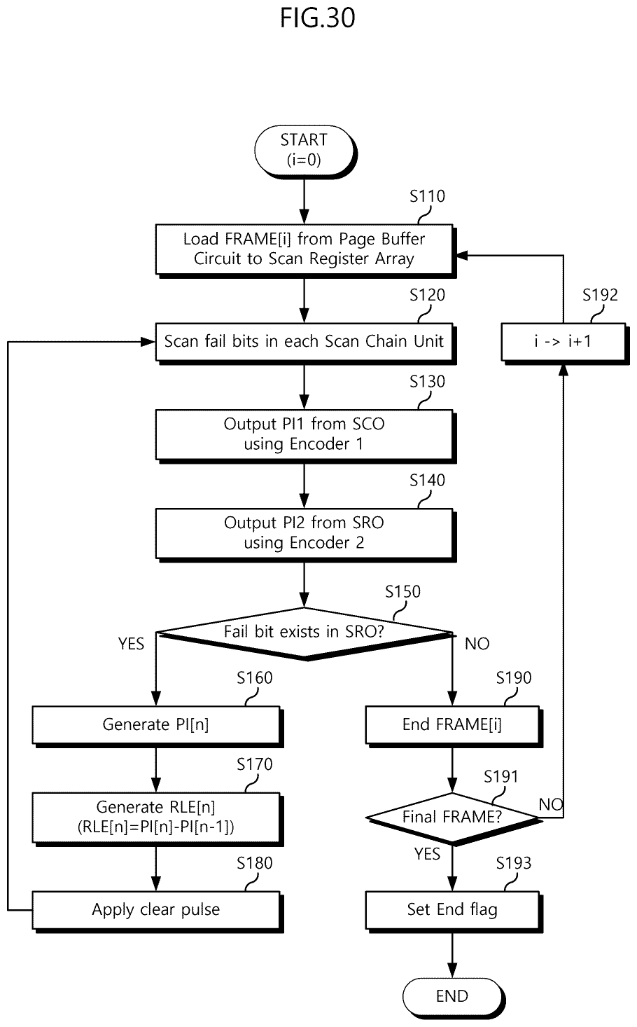

FIG. 30 is a flowchart for explaining the operation method of the scan register circuit shown in FIG. 20. Referring to FIG. 30, the scan register circuit 2000 may sequentially perform a fail bit scan operation from FRAME[0] to FRAME[255] and generate PI[n] and RLE[n].

In operation S110, the scan register circuit 2000 may load FRAME[0] data from the page buffer circuit 1130 to the scan register array 2100. FRAME[0] data may be the result of a 16-byte, 128-bit pass/fail of the page buffer circuit 1300. FRAME[0] data may be loaded into the scan registers of FRAME[0] of the scan register array 2100.

In operation S120, the scan register circuit 2000 may scan the fail bits in each scan chain unit. The scan register circuit 2000 may sequentially perform a fail bit scan operation of FRAME[0] data from 000h to 00Fh and generate a chain fail signal CF and a scan chain output signal SCO. The chain fail signal CF may be 1 if there is a fail bit in each scan chain unit and 0 if there is no fail bit. The scan chain output signal SCO may be a signal with all values set to 0 except for the highest priority 1 in the chain fail signal CF. The scan chain output signal SCO may be 16 bits.

In operation S130, the scan register circuit 2000 may output the first position index PI1 from the scan chain output signal SCO using the first encoder 2410 of the fail bit position finder 2200. The first encoder 2410 may output a 4-bit first position index PI1 from the scan chain output signal SCO using a 16×4 encoder.

In operation S140, the scan register circuit 2000 may generate a scan register output signal SRO from the scan chain unit where the first fail bit is located, and generate a second position index PI2 using the second encoder 2420. The second encoder 2420 may generate a scan register priority signal SRP from the scan register output signal SRO and output a 3-bit second position index PI2 using an 8×3 encoder.

In operation S150, the scan register circuit 2000 may determine whether a fail bit exists through the scan register output signal SRO. The scan register circuit 2000 may determine whether fail bit 1 exists in the scan register output signal SRO. If fail bit 1 exists, operation S160 may be performed, and if fail bit 1 does not exist, operation S190 may be performed.

In operation S150, the scan register circuit 2000 may determine whether the number of fail bits is greater than a certain number. If a predetermined number of fail bits 1 or more already exist, operation S190 may be performed.

In operation S160, the scan register circuit 2000 may generate a position index signal PI[n] using the frame address, the first position index, the second position index, and the end flag. For example, in the case of the first fail bit, PI[1] may be generated. PI[1] may include the row address and column address information of the first fail bit.

In operation S170, the scan register circuit 2000 may generate a run length encoding signal RLE[n] using the position index signal. For example, the subtract register 2440 may output RLE[1] using the difference between PI[1] and PI[0]. Referring to FIG. 28, RLE[1] is PI[1]-PI[0], which is 10d in decimal code and 000Ah in hex code.

In operation S180, the scan register circuit 2000 may apply a clear pulse to the scan register array 2100. The clear pulse may change the first fail bit from 1 to 0. After applying a clear pulse, the scan register circuit 2000 may repeatedly perform steps S120 to S170.

In operation S190, if there is no fail bit in the scan register output signal SRO, the scan register circuit 2000 may end the fail bit scan operation of FRAME[0] and generate an end flag of 1.

In operation S191, the scan register circuit 2000 may determine whether it is the final frame. If FRAME[0] is not the final frame, operation S192 may be performed. In operation S192, the scan register circuit 2000 may increment the frame address. For example, the scan register circuit 2000 may prepare the next frame FRAME[1]. If it is the final frame in operation S191 (YES), the end flag may be set and the fail bit scan operation may end (S193).

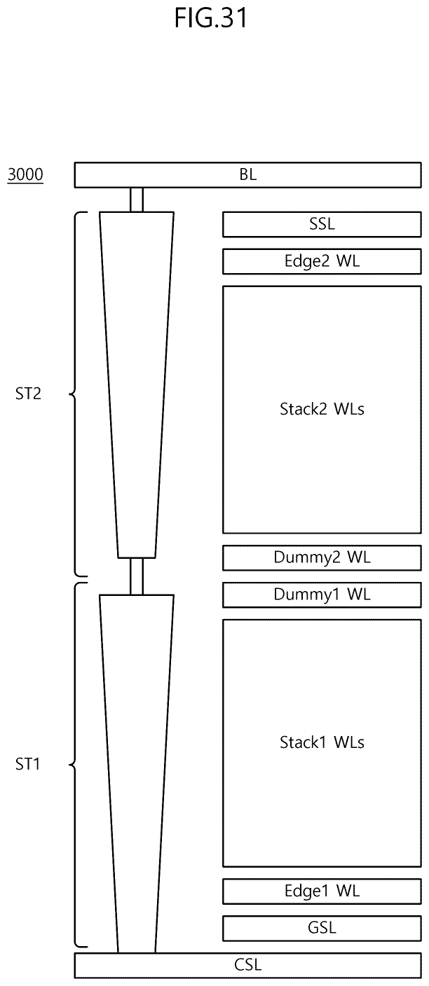

FIG. 31 is a diagram illustrating example embodiments of a memory device having a multi-stack structure. Referring to FIG. 31, the memory device 3000 may have a first stack ST1 and a second stack ST2. The first stack ST1 may be located at the bottom, and the second stack ST2 may be located at the top. There may be more than two stacks; example embodiments are not limited thereto. A height of the first stack ST1 may be the same as, greater than, or less than a height of the second stack ST2.

A pillar of the memory device 3000 may be formed by bonding the first and second stacks ST1 and ST2. A plurality of dummy word lines (e.g., Dummy1 WL and Dummy2 WL) may be included at junctions of the first and second stacks ST1 and ST2. The first stack ST1 may be positioned between the common source line CSL and the first dummy word line Dummy1 WL. The second stack ST2 may be positioned between the second dummy word line Dummy2 WL and the bit line BL.

The first stack ST1 may include a ground selection line GSL, a first edge word line Edge1 WL, and first stack word lines Stack1 WLs. The second stack ST2 may include second stack word lines Stack2 WLs and second edge word lines Edge2 WL. Memory cells connected to the first and second edge word lines Edge1 WL and Edge2 WL may store bit data different from the other memory cells. For example, memory cells connected to the first and second edge word lines Edge1 WL and Edge2 WL may be SLC or MLC, and memory cells connected to the other word lines may be TLC or QLC.

The memory device 3000 may include a scan register circuit. The scan register circuit may obtain information about the scan register where the fail result is stored through a scan operation. The scan register circuit may use the information about the scan register where the fail result is stored to calculate a position index indicating the position of the fail bit.

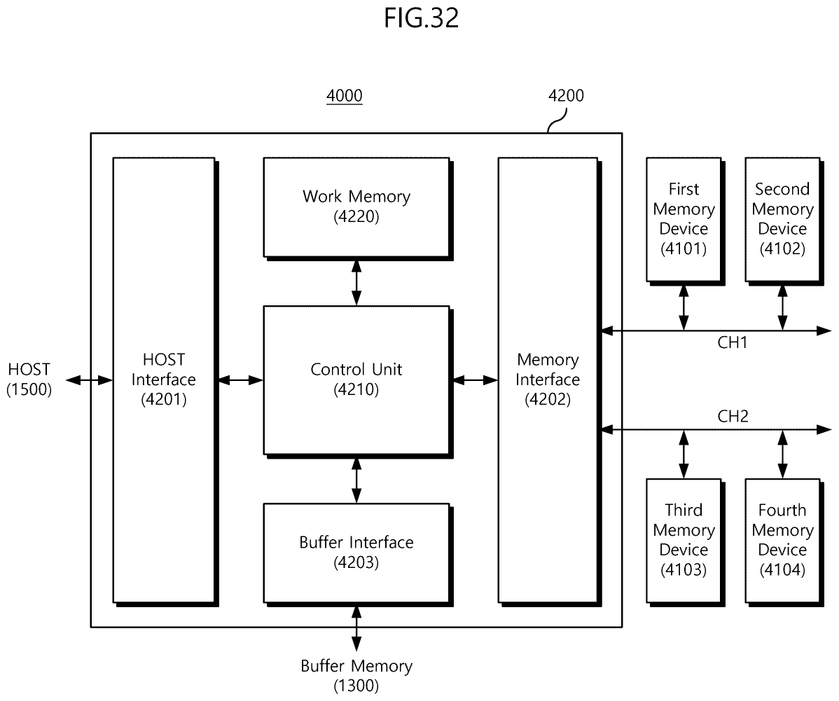

FIG. 32 is a block diagram illustrating an example in which a storage device according to an embodiment of the present disclosure is implemented with a solid state drive (SSD). Referring to FIG. 32, an SSD 4000 may include a plurality of memory devices 4101 to 4104 and an SSD controller 4200.

The first and second memory devices 4101 and 4102 may be connected with the SSD controller 4200 through a first channel CH1. The third and fourth memory devices 4103 and 4104 may be connected with the SSD controller 4200 through a second channel CH2. The number of channels connected with the SSD controller 4200 may be 2 or more. The number of memory devices connected with one channel may be 2 or more.

The SSD controller 4200 may include a host interface 4201, a memory interface 4202, a buffer interface 4203, a control unit 4210, and a work memory 4220. The SSD controller 4200 may be connected with a host 1500 through the host interface 4201. Depending on a request of the host 1500, the SSD controller 4200 may write data in the corresponding memory device or may read data from the corresponding memory device.

The SSD controller 4200 may be connected with the plurality of memory devices 4101 to 4104 through the memory interface 4202 and may be connected with a buffer memory 1300 through the buffer interface 4203. The memory interface 4202 may provide data, which are temporarily stored in the buffer memory 1300, to the memory devices through the channels CH1 and CH2. The memory interface 4202 may transfer the data read from the memory devices 4101 to 4104 to the buffer memory 1300.

The control unit 4210 may analyze and process the signal received from the host 1500. The control unit 4210 may control the host 1500 or the memory devices 4101 to 4104 through the host interface 4201 or the memory interface 4202. The control unit 4210 may control operations of the memory devices 4101 to 4104 by using firmware for driving the SSD 4000.

The SSD controller 4200 may manage data to be stored in the memory devices 4101 to 4104. In the sudden power-off event, the SSD controller 4200 may back the data stored in the work memory 4220 or the buffer memory 1300 up to the memory devices 4101 to 4104.

According to various example embodiments, it may be possible to reduce a test time taken to perform the margin read test operation, and/or to perform the margin read test operation in high speed. Alternatively or additionally there may be a reduction in power consumption according to various example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While inventive concepts has been described with reference to embodiments thereof, it will be apparent to those of ordinary skill in the art that various changes and modifications may be made thereto without departing from the spirit and scope of the present disclosure as set forth in the following claims. Additionally, example embodiments are not necessarily mutually exclusive with one another. For example, some example embodiments may include one or more features described with reference to one or more figures, and may also include one or more other features described with reference to one or more other figures.

What is claimed is:

1. A memory device comprising:
a memory cell array configured to store data;
a page buffer circuit configured to at least one of store the data stored in the memory cell array or read the data stored in the memory cell array; and
a scan register circuit configured to receive pass/fail results of data from the page buffer circuit and to store the pass/fail result in a plurality of scan registers,
wherein the scan register circuit is configured to use information of scan registers in which fail results are stored through a fail bit scan operation and to generate position index signals indicating the positions of the fail bits.

2. The memory device of claim 1,
wherein the scan register circuit is configured to generate run-length encoding signals that compress and represent a number of data repeated between fail bits.

3. The memory device of claim 1,
wherein the scan register circuit includes,
a scan register array having a plurality of scan chain units, each scan chain unit having a plurality of scan registers, each scan register configured to store a pass/fail result of data; and
a fail bit position finder configured to receive information of the scan registers where the fail results are stored and information of the scan register where the fail result is first stored from each of the scan chain units, and to output the position index signals indicating the position of the fail bits.

4. The memory device of claim 3,
wherein a position index signal includes an end flag indicating whether a fail bit exists or not.

5. The memory device of claim 3,
wherein the fail bit position finder includes,
a first encoder configured to receive a scan chain output signal and to output a first position index;
a second encoder configured to receive a scan register output signal and to output a second position index;
an adder configured to output a position index signal using the first position index and the second position index; and
a subtract register configured to output a run length encoding signal using a difference between the position index signals.

6. The memory device of claim 5,
wherein the each scan chain unit includes,
a pulse gate configured to receive a clear pulse and to output a clock signal;
a plurality of scan registers connected in series and configured to perform a scan chain operation in response to a clock signal of the pulse gate; and
a priority filter configured to receive scan a chain operation result from the plurality of scan registers and to output the scan chain output signal.

7. The memory device of claim 6,
wherein each scan chain unit further includes,
a scan register output circuit configured to receive information about scan registers storing fail results from the plurality of serially connected scan registers and to output the scan register output signal.

8. The memory device of claim 7,
wherein the scan register output circuit includes selection circuits connected in series, and is configured to generate the scan register output signal from each selection circuit.

9. The memory device of claim 8,
wherein the second encoder includes,
a priority encoder configured to receive the scan register output signal and to generate a scan register priority signal; and
a scan register encoder configured to receive the scan register priority signal and to generate the second position index.

10. The memory device of claim 9,
wherein the adder is configured to output the position index signal using the first position index and the second position index.

11. A scan register circuit of a memory device, comprising:
a scan register array comprising a plurality of frames, each frame having a plurality of scan chain units, each scan chain unit having a plurality of scan registers, each scan register configured to store a pass/fail result of data; and
a fail bit position finder configured to use information of scan registers in which fail results are stored through a fail bit scan operation and to generate position index signals indicating the positions of the fail bits.

12. The scan register circuit of claim 11,
wherein the each scan chain unit includes,
a pulse gate configured to receive a clear pulse and output a clock signal;
a plurality of scan registers connected in series and configured to perform a scan chain operation in response to a clock signal of the pulse gate; and
a priority filter configured to receive scan a chain operation result from the plurality of scan registers and to output the scan chain output signal.

13. The scan register circuit of claim 12,
wherein each scan chain unit further includes,
a scan register output circuit configured to receive information about scan registers storing fail results from the plurality of serially connected scan registers and to output the scan register output signal.

14. The scan register circuit of claim 13,
wherein the fail bit position finder,
is configured to receive information of a scan register in which a fail result is stored and information of a scan register in which a fail result is first stored from each scan chain unit;
to calculate a first position index indicating the position of a fail bit;
to receive the scan register output signal from the scan register output circuit; and
to calculate a second position index indicating the position of the fail bit.

15. The scan register circuit of claim 14,
wherein the fail bit position finder includes,
an adder configured to output a position index signal using the first position index and the second position index; and
a subtract register configured to output a run length encoding signal using a difference between the position index signals.

16. The scan register circuit of claim 15, wherein
the position index signal indicating the position of the fail bit includes a row address and a column address,
the row address of the fail bit includes the address of the frame and the address of the first position index, and
the column address of the fail bit includes the address of the second position index.

17. The scan register circuit of claim 16,
wherein a position index signal includes an end flag to indicate whether a fail bit exists or not.

18. The scan register circuit of claim 17,
wherein the adder outputs the position index signal using the end flag, the address of the frame, the address of the first position index, and the address of the second position index.

19. A scan register circuit of a memory device, comprising:
a scan register array having a plurality of frames, each frame having a plurality of scan chain units, each scan chain unit having a plurality of scan registers, each scan register storing a pass/fail result of data; and
a fail bit position finder configured to use information of scan registers in which fail results are stored through a scan operation of the plurality of scan registers and generate position index signals indicating the positions of the fail bits,
wherein the fail bit position finder receives the information of the scan registers where the fail results are stored and the information of the scan register where the fail result are first stored from each scan chain unit through a fail bit scan operation, and outputs the position index signals representing row addresses and column addresses of the fail bits.

20. The scan register circuit of claim 19,
wherein the fail bit position finder generates run-length encoding signals that compress and represent a number of data repeated between fail bits.
